(19) United States
(12) Patent Application Publication
(10) Pub. No.: US 2025/0393363 A1
(43) Pub. Date: Dec. 25, 2025

(54) LIGHT EMITTING DEVICE AND DISPLAY APPARATUS INCLUDING THE SAME

(71) Applicant: SAMSUNG ELECTRONICS CO., LTD., Suwon-si (KR)

(72) Inventors: Hanul YOO, Suwon-si (KR); Sangbum LEE, Suwon-si (KR); Dongwan KO, Suwon-si (KR); Junghee KWAK, Suwon-si (KR); Mihyun KIM, Suwon-si (KR); Hyeseok NOH, Suwon-si (KR); Seungchan LEE, Suwon-si (KR); Taegyeong LEE, Suwon-si (KR); Juyeon JEONG, Suwon-si (KR)

(73) Assignee: SAMSUNG ELECTRONICS CO., LTD., Suwon-si (KR)

(21) Appl. No.: 19/058,924

(22) Filed: Feb. 20, 2025

(30) Foreign Application Priority Data
Jun. 19, 2024 (KR) 10-2024-0079798

(51) Int. Cl. H10H 29/49; H10H 29/855

(52) U.S. Cl. CPC H10H 29/49; H10H 29/855

(57) ABSTRACT

A light emitting device includes a substrate, a light emitting structure on a pixel array region of the substrate, a grid electrode on the light emitting structure, a plurality of lenses on the light emitting structure, and a common electrode on the edge region of the substrate. The substrate includes the pixel array region and an edge region. The pixel array region includes a plurality of pixel regions. The grid electrode is provided between two adjacent pixel regions from among the plurality of pixel regions of the substrate. The light emitting structure includes a semiconductor stack including a first semiconductor layer, an active layer, and a second semiconductor layer. The second semiconductor layer is electrically coupled with the common electrode through the grid electrode.

### CROSS-REFERENCE TO RELATED APPLICATION

This application claims benefit of priority under 35 U.S.C. § 119 to Korean Patent Application No. 10-2024-0079798, filed on Jun. 19, 2024, in the Korean Intellectual Property Office, the disclosure of which is incorporated by reference herein in its entirety.

### BACKGROUND

### 1. Field

The present disclosure relates generally to light emitting devices, and more particularly, to a light emitting device including a grid electrode and lenses.

### 2. Description of Related Art

A light emitting device, such as, but not limited to, a light emitting diode (LED), may refer to a device in which a material contained in the device emits light (e.g., visible, infrared, or the like). Light emitting diodes (LEDs) may be widely used as light sources for various display apparatuses such as, but not limited to, lighting devices, televisions (TVs), mobile phones, personal computers (PCs), laptops, personal digital assistants (PDAs), digital cameras, camera recorders, viewfinders, microdisplays, three-dimensional (3D) displays, virtual reality or augmented reality displays, or the like. Recently, micro-unit and/or nano-unit ultra-small LEDs using group II-VI or group III-V compound semiconductors may have been developed. There is an increasing need for light emitting diodes (LEDs) to achieve uniform light emission.

### SUMMARY

One or more example embodiments of the present disclosure provide a light emitting device having improved image characteristics and a display apparatus including the same, when compared to a related light emitting device.

According to an aspect of the present disclosure, a light emitting device includes a substrate, a light emitting structure on a pixel array region of the substrate, a grid electrode on the light emitting structure, a plurality of lenses on the light emitting structure, and a common electrode on the edge region of the substrate. The substrate includes the pixel array region and an edge region. The pixel array region includes a plurality of pixel regions. The grid electrode is provided between two adjacent pixel regions from among the plurality of pixel regions of the substrate. The light emitting structure includes a semiconductor stack including a first semiconductor layer, an active layer, and a second semiconductor layer. The second semiconductor layer is electrically coupled with the common electrode through the grid electrode.

According to an aspect of the present disclosure, a light emitting device includes a substrate, a light emitting structure on each of a plurality of pixel regions of the substrate, a passivation layer on the light emitting structure, a grid electrode in the passivation layer and on the light emitting structure and between two adjacent pixel regions from among the plurality of pixel regions, and a plurality of lenses on a top surface of the passivation layer. The substrate includes a pixel array region and an edge region. The pixel array region includes the plurality of pixel regions. The light emitting structure includes a semiconductor stack including a first semiconductor layer, an active layer, and a second semiconductor layer. The second semiconductor layer is electrically coupled with a common electrode through the grid electrode.

According to an aspect of the present disclosure, a display apparatus includes a lower substrate, an upper substrate, a grid electrode on the light emitting structure, a plurality of lenses on the light emitting structure, a common electrode provided on the edge region of the upper substrate and electrically coupled with another second bonding electrode from among the plurality of second bonding electrodes, and a conductive pattern on the grid electrode and on the common electrode. The lower substrate includes a semiconductor substrate, a plurality of wiring lines on a bottom surface of the semiconductor substrate, a plurality of transistors on a top surface of the semiconductor substrate, a first bonding insulating layer on the top surface of the semiconductor substrate, and first bonding electrodes within the first bonding insulating layer. The upper substrate includes a second bonding insulating layer on the first bonding insulating layer, a plurality of second bonding electrodes on the first bonding electrodes, and a light emitting structure on at least one of the plurality of second bonding electrodes. The upper substrate includes a pixel array region and an edge region. The pixel array region includes a plurality of pixel regions. The grid electrode is electrically coupled with the common electrode through the conductive pattern. The grid electrode is between two adjacent pixel regions from among the plurality of pixel regions of the upper substrate. The light emitting structure includes a semiconductor stack includes a first semiconductor layer, a second semiconductor layer on the first semiconductor layer, and an active layer between the first semiconductor layer and the second semiconductor layer. The grid electrode is electrically coupled with the second semiconductor layer.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1A is a plan view illustrating a light emitting device, according to embodiments;

FIG. 1B illustrates a plan view in which a region II of FIG. 1A is enlarged and a plan view in which region II′ is enlarged, according to embodiments;

FIG. 1C illustrates a cross-sectional view taken along line III-III′ of FIG. 1B and a cross-sectional view taken along line IV-IV′ of FIG. 1B, according to embodiments;

FIG. 1D is an enlarged view of a region V of FIG. 1C, according to embodiments;

FIG. 1E is a diagram for describing pixel regions, according to embodiments;

FIG. 1F illustrates a cross-sectional view taken along the line III-III′ of FIG. 1B and a cross-sectional view taken along the line IV-IV′ of FIG. 1B, according to embodiments;

FIG. 1G is an enlarged view of a region V of FIG. 1C, according to embodiments;

FIG. 2A is a cross-sectional view illustrating a light emitting device, according to embodiments;

FIG. 2B is a cross-sectional view illustrating a grid electrode, according to embodiments;

FIG. 3A is a diagram illustrating a light emitting device, according to embodiments;

FIG. 3B is a diagram illustrating a light emitting device, according to embodiments;

FIG. 3C is a cross-sectional view illustrating a grid electrode, according to embodiments;

FIG. 3D is a cross-sectional view illustrating a grid electrode, according to embodiments;

FIG. 4A is a plan view illustrating a light emitting device, according to embodiments;

FIG. 4B illustrates a cross-sectional view taken along line III-III′ of FIG. 4A and a cross-sectional view taken along line IV-IV′ of FIG. 4A;

FIG. 5 is a plan view illustrating an arrangement of a grid electrode, according to embodiments;

FIGS. 6A to 6F are cross-sectional views illustrating a manufacturing method of a light emitting device, according to embodiments;

FIGS. 7A to 7D are cross-sectional views illustrating a manufacturing method of a light emitting device, according to embodiments; and

FIG. 8 is a schematic diagram of an electronic device including a light emitting device, according to embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

As used herein, each of the terms “AlInGaAs”, “AlInGaP”, “AlN”, “Al₂O₃”, “CaF₂”, “GaAs”, “GaN”, “GaP”, “InₓAl_{y}Ga_{1-x-y}N”, “InAs”, “InGaN”, “InP”, “LiAlO₂”, “LiGaO₂”, “MgAl₂O₄”, “MgF₂”, “MgO”, “SiC”, “SiCN”, “SiCO”, “SiCON”, “SiGe”, “Si₃N₄”, “SiO₂”, “SiOₓN_{y}”, “SnZnO₃”, “TaN”, “TiAlN”, “TiCu”, “TiN”, “TiO₂”, “TiSiN”, “Zn₍₁₋ₓ₎MgₓO”, “ZnO”, “ZrO₂”, and the like may refer to a material made of elements included in each of the terms and is not a chemical formula representing a stoichiometric relationship.

Hereinafter, a light emitting device, a display apparatus including the light emitting device, and a method of manufacturing the light emitting device according to the present disclosure are described below.

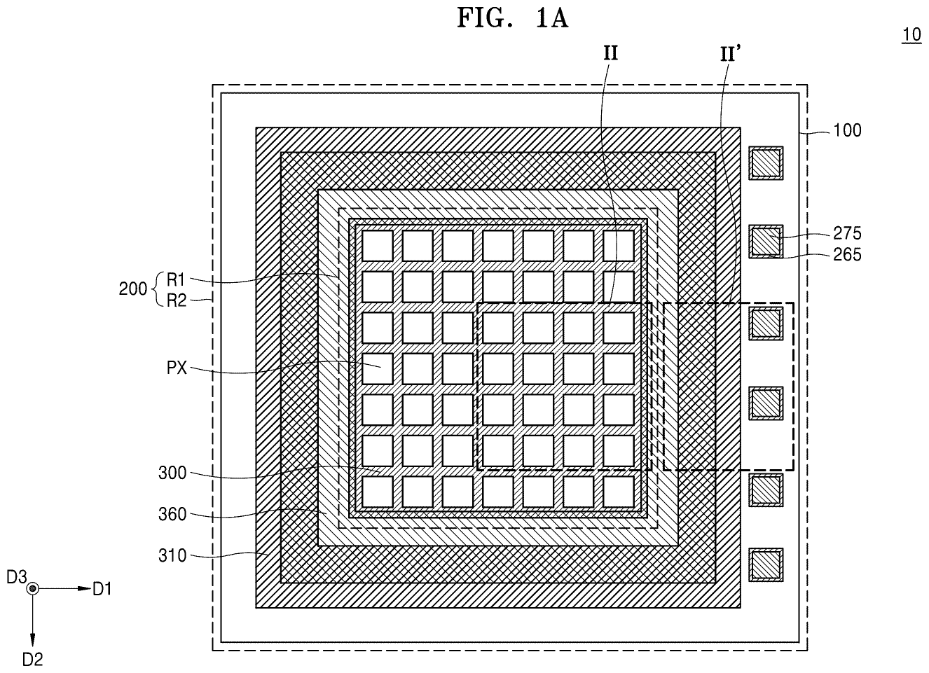

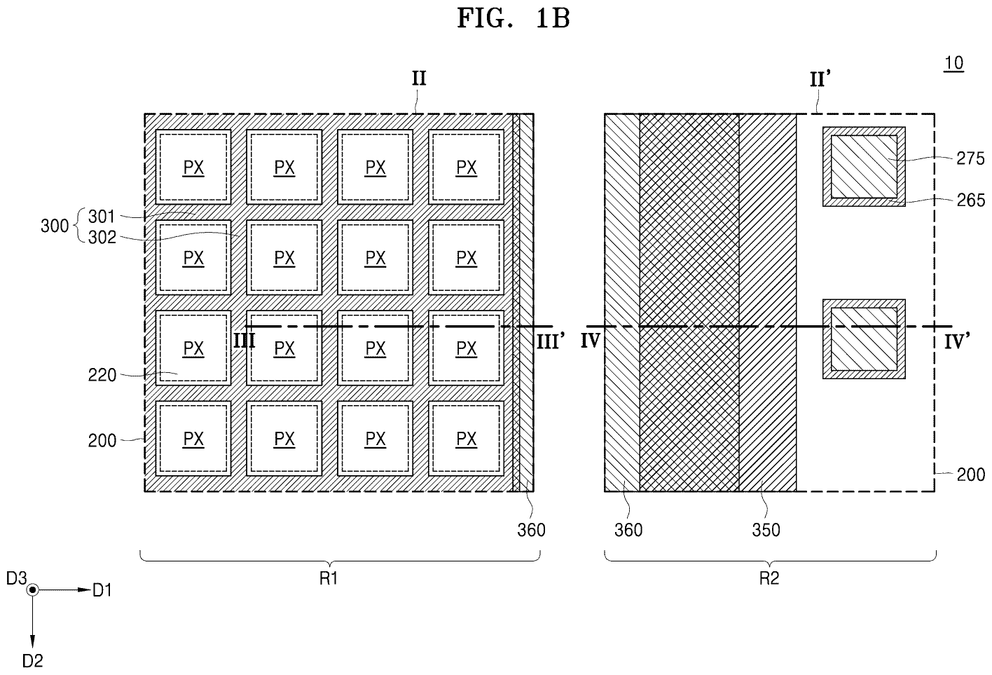

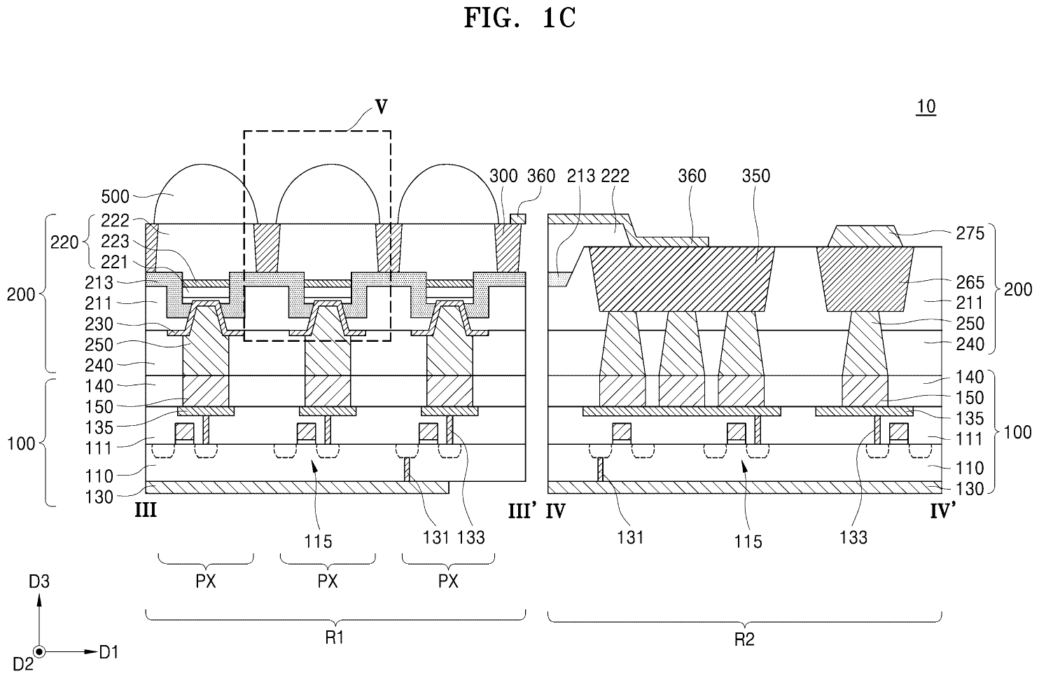

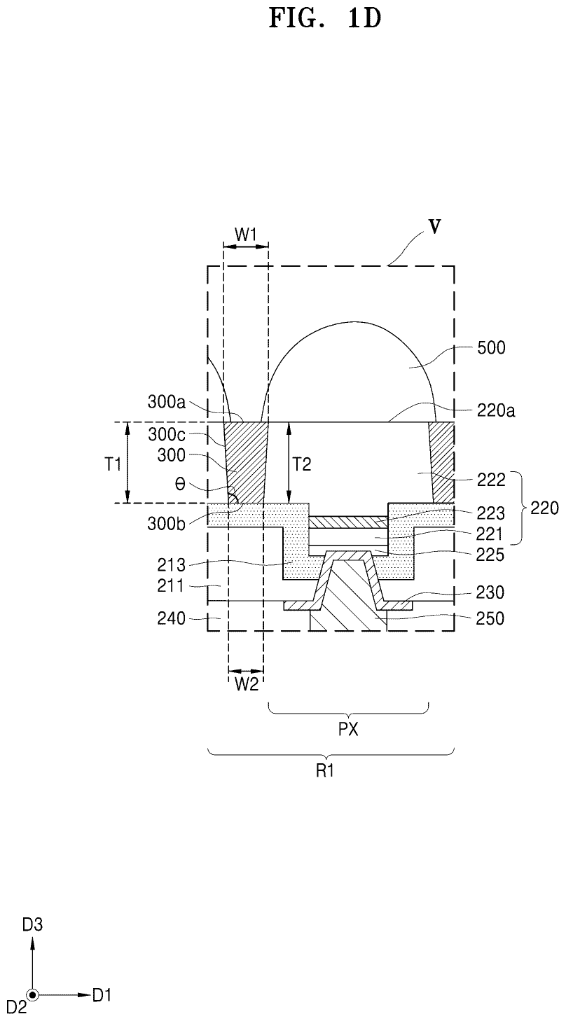

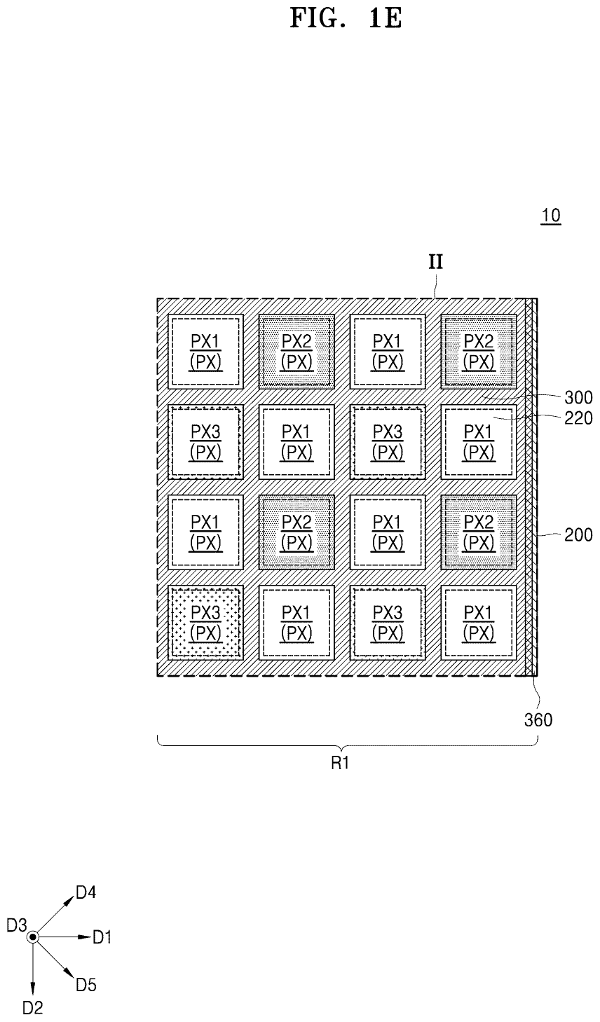

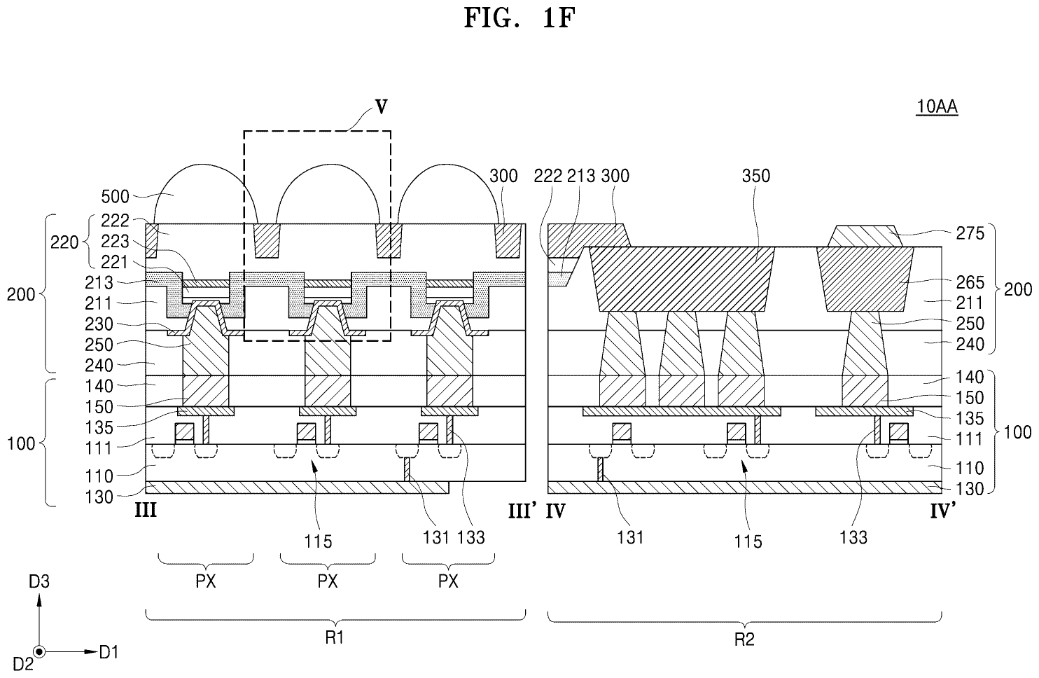

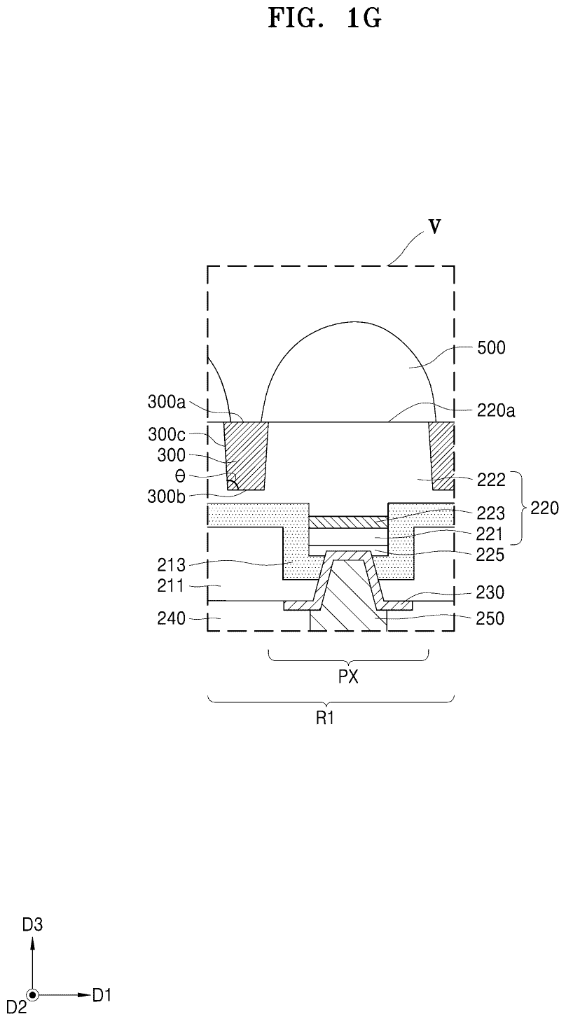

FIG. 1A is a plan view illustrating a light emitting device, according to embodiments. FIG. 1B illustrates a plan view in which region II of FIG. 1A is enlarged and a plan view in which region II′ is enlarged, according to embodiments. FIG. 1C illustrates a cross-sectional view taken along the line III-III′ of FIG. 1B and a cross-sectional view taken along the line IV-IV′ of FIG. 1B, according to embodiments. FIG. 1D is an enlarged view of a region V of FIG. 1C, according to embodiments. FIG. 1E is a cross-sectional view illustrating pixel regions, according to embodiments, which correspond to an enlarged plan view of the region II of FIG. 1B.

Referring to FIGS. 1A and 1B, a display apparatus may include a light emitting device 10. The light emitting device 10 may include a lower substrate 100, an upper substrate 200, a grid electrode 300, a conductive pattern 360, and a common electrode 350. The lower substrate 100 may include a circuit board. The lower substrate 100 may include driving circuits and may function as a driving circuit board. The driving circuits may include a plurality of transistors 115 as shown in FIG. 1C. For example, the driving circuits may include an application-specific integrated circuit (ASIC). As another example, the lower substrate 100 may include a flexible substrate. In such an example, the display apparatus including the light emitting device 10 may function as a variable display apparatus and/or a curved display apparatus.

The upper substrate 200 may be disposed on a top surface of the lower substrate 100. The upper substrate 200 may include a pixel substrate and/or a light emitting substrate. In a plan view, the upper substrate 200 may have a pixel array region R1 and an edge region R2. The pixel array region R1 of the upper substrate 200 may correspond to a center region of the upper substrate 200. The pixel array region R1 of the upper substrate 200 may include a plurality of pixel regions PX. Components of pixels may be provided respectively on the pixel regions PX. Each of the components on the pixel regions PX may be configured to emit light of one or more wavelengths. For example, for each of the components on the pixel regions PX may be configured to emit light of one or more colors.

The grid electrode 300 may be disposed on the pixel array region R1 of the upper substrate 200. The grid electrode 300 may be disposed between the pixel regions PX of the upper substrate 200. For example, in a plan view, the grid electrode 300 may surround each of the pixel regions PX.

As shown in FIG. 1B, the grid electrode 300 may have, in a plan view, a grid shape and/or a mesh shape. However, the present disclosure is not limited in this regard, and the grid electrode 300 may have other shapes without departing from the scope of the present disclosure. For example, the grid electrode 300 may include first portions 301 and second portions 302. The first portions 301 may extend in a direction parallel to a first direction D1 and may be spaced apart from each other in a second direction D2. The second portions 302 may extend in a direction parallel to the second direction D2 and may be spaced apart from each other in the first direction D1. The second portions 302 may be connected to the first portions 301.

The edge region R2 of the upper substrate 200 may surround the pixel array region R1 in a plan view. The edge region R2 of the upper substrate 200 may be provided between the pixel array region R1 and the sidewalls of the upper substrate 200 in a plan view. The light emitting device 10 may further include a pad electrode 265 and a bonding pad 275. The pad electrode 265 and the bonding pad 275 may be provided on the top surface of the edge region R2 of the upper substrate 200. The pad electrode 265 and the bonding pad 275 may be provided at one side of the pixel array region R1 of the upper substrate 200. For example, the bonding pad 275 of the upper substrate 200 may be provided between the pixel array region R1 and the first sidewall of the upper substrate 200. The bonding pad 275 may be disposed on the pad electrode 265. The bonding pad 275 may be electrically connected to the grid electrode 300 and the plurality of transistors 115 of the lower substrate 100.

The light emitting device 10 may be electrically connected to an external device through the bonding pad 275. As used herein, an electrical connection between any two components may include a direct connection and/or an indirect connection through a third component. The upper substrate 200 may include a plurality of bonding pads 275 and a plurality of pad electrodes 265. The number, shape, and arrangement of the bonding pads 275 may be variously modified without being limited to the illustration. For example, the number of bonding pads 275 of the upper substrate 200 may be determined according to the number of pixel regions PX and/or a driving method of driving circuits included in the lower substrate 100.

The common electrode 350 may be provided on the edge region R2 of the upper substrate 200. The common electrode 350 may be spaced apart from the pixel array region R1 of the upper substrate 200 in a plan view. The common electrode 350 may be provided between the grid electrode 300 and the bonding pads 275. For example, in a plan view, the common electrode 350 may have a square loop shape. In such an example, the common electrode 350 may surround the pixel array region R1 and the grid electrode 300 in a plan view. A planar shape of the common electrode 350 may not be limited to the illustration and may be variously modified.

The conductive pattern 360 may be provided on the pixel array region R1 and the edge region R2 of the upper substrate 200. For example, the conductive pattern 360 may be provided on an outer region of the pixel array region R1 of the upper substrate 200. The conductive pattern 360 may be disposed on the grid electrode 300 and the common electrode 350. For example, the conductive pattern 360 may cover a part of a top surface of the grid electrode 300. The grid electrode 300 may be electrically connected to the common electrode 350 through the conductive pattern 360. Hereinafter, for ease of description, the plurality of pad electrodes 265 and/or the plurality of bonding pads 275 may be described and/or referred to as a single pad electrode 265 and/or a single bonding pad 275. However, the present disclosure is not limited in this regard.

Referring to FIGS. 1B and 1C, the light emitting device 10 may include lenses 500 in addition to the lower substrate 100, the upper substrate 200, the grid electrode 300, the conductive pattern 360, and the common electrode 350. The lower substrate 100 may include a first substrate 110, a plurality of transistors 115, a wiring line 130, a first bonding insulating layer 140, and first bonding electrodes 150. The first substrate 110 may be a first semiconductor substrate. For example, the first substrate 110 may be and/or may include a semiconductor material and/or a compound semiconductor material. As another example, the semiconductor material may be and/or may include, but not be limited to, silicon (Si), germanium (Ge), or the like. The compound semiconductor material may be and/or may include, but not be limited to, silicon-germanium (SiGe), silicon carbide (SiC), gallium arsenide (GaAs), indium arsenide (InAs), or indium phosphate (InP). The first direction D1 may extend parallel to the bottom surface of the first substrate 110 and parallel to one side surface of the lower substrate 100. The second direction D2 may be parallel to the bottom surface of the first substrate 110 and may cross the first direction D1. For example, the second direction D2 may be perpendicular to the first direction D1. A third direction D3 may be substantially perpendicular to the bottom surface of the first substrate 110. The third direction D3 may be a vertical direction.

The plurality of transistors 115 may be provided on the first substrate 110. For example, the plurality of transistors 115 may be provided on the pixel array region R1 and the edge region R2 of the upper substrate 200. As used herein, a component being disposed on the pixel array region R1 of the upper substrate 200 may include a component being disposed on a top surface of the pixel array region R1 of the upper substrate 200, a component being disposed on a bottom surface of the pixel array region R1 of the upper substrate 200, and a component being disposed within the pixel array region R1 of the upper substrate 200. A component being disposed on the edge region R2 of the upper substrate 200 may include a component being disposed on the upper surface of the edge region R2 of the upper substrate 200, a component being disposed on the lower surface of the edge region R2 of the upper substrate 200, and a component being disposed in the edge region R2 of the upper substrate 200.

The plurality of transistors 115 may control operations of components in the pixel regions PX. Each of the plurality of transistors 115 may include a gate pattern and impurity regions. The impurity regions may be provided in the first substrate 110 and may function as source/drain regions. The impurity regions may include a first impurity region and a second impurity region. One of the first impurity region and the second impurity region may be a source region, and the other may be a drain region. The first impurity region may be any one of a plurality of first impurity regions, and the second impurity region may be any one of a plurality of second impurity regions.

The wiring line 130 may be provided on a bottom surface of the first substrate 110. For example, the wiring line 130 may be provided on the bottom surface of the pixel array region R1 and the bottom surface of the edge region R2 of the upper substrate 200. The wiring line 130 may include a conductive material such as, but not limited to, a metal, or the like.

The lower substrate 100 may further include lower vias 131. The lower vias 131 may be provided in the first substrate 110. For example, the lower vias 131 may penetrate the first substrate 110. The lower vias 131 may be connected to the plurality of transistors 115. For example, the lower vias 131 may be connected to the first impurity regions of the plurality of transistors 115. Thus, the plurality of transistors 115 may be electrically connected to the wiring line 130 through the lower vias 131. The lower vias 131 may include a conductive material such as metal.

The lower substrate 100 may further include a lower insulating layer 111 and upper vias 133. The lower insulating layer 111 may be provided on a top surface of the first substrate 110 to cover the plurality of transistors 115. The lower insulating layer 111 may be a single layer or multiple layers. The lower insulating layer 111 may include a silicon-based insulating material. The silicon-based insulating material may be and/or may include, but not be limited to, silicon oxide (SiO₂), silicon nitride (Si₃N₄), silicon oxynitride (SiOₓN_{y}), tetraethyl orthosilicate (TEOS), or the like.

The upper vias 133 may be provided in the lower insulating layer 111. For example, the upper vias 133 may penetrate the lower insulating layer 111 to be electrically connected to the plurality of transistors 115. For example, the upper vias 133 may be connected to the second impurity regions of the plurality of transistors 115. Thus, the plurality of transistors 115 may be electrically connected to the upper vias 133. The upper vias 133 may include a conductive material such as, but not limited to, a metal, or the like.

The first bonding insulating layer 140 may be provided on the lower insulating layer 111. The first bonding insulating layer 140 may include a silicon-containing insulating material. The silicon-containing insulating material may be and/or may include, but not be limited to, silicon oxide (SiO₂), silicon nitride (Si₃N₄), silicon oxynitride (SiOₓN_{y}), silicon carbon nitride (SiCN), silicon carbide oxide (SiCO), silicon carbide oxynitride (SiCON), and/or combinations thereof.

The first bonding electrodes 150 may be provided in the first bonding insulating layer 140. The first bonding electrodes 150 may penetrate the first bonding insulating layer 140. Top surfaces of the first bonding electrodes 150 may not be covered by the first bonding insulating layer 140. The top surface of the lower substrate 100 may include a top upper surface of the first bonding insulating layer 140 and top surfaces of the first bonding electrodes 150. The first bonding electrodes 150 may include, for example, a metal such as, but not limited to, copper (Cu). The first bonding electrodes 150 may be provided on the pixel array region R1 and the edge region R2 of the upper substrate 200. The first bonding electrodes 150 may be provided to the pixel regions PX on the pixel array region R1 of the upper substrate 200, respectively. The first bonding electrodes 150 may be laterally spaced apart from each other.

The lower substrate 100 may further include conductive lines 135. The conductive lines 135 may be disposed on the pixel array region R1 and the edge region R2 of the upper substrate 200. The conductive lines 135 may be provided between the upper vias 133 and the first bonding electrodes 150 to be electrically connected to the upper vias 133 and the first bonding electrodes 150. Accordingly, the first bonding electrodes 150 may be electrically connected to the plurality of transistors 115 through the conductive lines 135. The conductive lines 135 may further extend between the lower insulating layer 111 and the first bonding insulating layer 140. The conductive lines 135 may include a conductive material such as, but not limited to, a metal, or the like.

The upper substrate 200 may include a second bonding insulating layer 240, a second bonding electrode 250, a reflective layer 213, and a light emitting structure 220. The second bonding insulating layer 240 may be disposed on the first bonding insulating layer 140. The second bonding insulating layer 240 may be and/or may include a silicon-containing insulating material. The silicon-containing insulating material may be and/or may include, but not be limited to, silicon oxide (SiO₂), silicon nitride (Si₃N₄), silicon oxynitride (SiOₓN_{y}), silicon carbon nitride (SiCN), silicon carbide oxide (SiCO), silicon carbide oxynitride (SiCON), and/or combinations thereof.

The second bonding electrodes 250 may be provided in the pixel array region R1 and the edge region R2 of the upper substrate 200. The second bonding electrodes 250 may be spaced apart from each other. When the second bonding electrodes 250 are provided in the pixel array region R1 of the upper substrate 200, the second bonding electrodes 250 may be provided in the pixel regions PX of the upper substrate 200, respectively. The second bonding electrodes 250 may be provided in the second bonding insulating layer 240. The second bonding electrodes 250 may penetrate the second bonding insulating layer 240. The bottom surfaces of the second bonding electrodes 250 may not be covered by the second bonding insulating layer 240. The bottom surface of the upper substrate 200 may include a bottom surface of the second bonding insulating layer 240 and bottom surfaces of the second bonding electrodes 250. The second bonding electrodes 250 may include, for example, a metal such as, but not limited to, copper (Cu).

For example, a top surface of each of the second bonding electrodes 250 may have a width smaller than a bottom surface thereof. For example, an upper portion of each of the second bonding electrodes 250 may have a top surface and an inclined upper sidewall. However, the shape of each of the second bonding electrodes 250 is not limited thereto.

The upper substrate 200 may be directly bonded to the lower substrate 100. Direct bonding may be formed by a hybrid bonding process. Bottom surfaces of the second bonding electrodes 250 may be in direct contact with top surfaces of the first bonding electrodes 150. The bottom surfaces of the second bonding electrodes 250 may be directly bonded to the top surfaces of the first bonding electrodes 150. The interfaces between the second bonding electrodes 250 and the first bonding electrodes 150 directly bonded to each other may not be distinguished. The interfaces between the second bonding electrodes 250 and the first bonding electrodes 150 directly bonded to each other may be and/or may include a virtual interface. However, the present disclosure is not limited thereto. The second bonding electrodes 250 may include the same metal (e.g., copper (Cu)) as the first bonding electrodes 150. The bottom surface of the second bonding insulating layer 240 may be in direct contact with the top surface of the first bonding insulating layer 140. The bottom surface of the second bonding insulating layer 240 may be directly bonded to the top surface of the first bonding insulating layer 140. The second bonding insulating layer 240 may include the same insulating material as the first bonding insulating layer 140. For example, an interface between the second bonding insulating layer 240 and the first bonding insulating layer 140 may not be distinguished.

The upper substrate 200 may further include an upper insulating layer 211. The upper insulating layer 211 may be provided on the second bonding insulating layer 240. The upper insulating layer 211 may be and/or may include a silicon-based insulating material. The silicon-based insulating material may be and/or may include, but not be limited to, silicon oxide (SiO₂), silicon nitride (Si₃N₄), silicon oxynitride (SiOₓN_{y}), tetraethyl orthosilicate (TEOS), or the like.

Hereinafter, configurations on and within the pixel array region R1 of the upper substrate 200 are described.

The upper substrate 200 may further include reflective electrodes 230. The reflective electrodes 230 may be provided on the second bonding electrodes 250 to be electrically connected to the second bonding electrodes 250. For example, the reflective electrodes 230 may be in contact with top surfaces of the second bonding electrodes 250. The reflective electrodes 230 may further cover inclined upper sidewalls of the second bonding electrodes 250. The plurality of reflective electrodes 230 are laterally spaced apart from each other and may be electrically separated from each other. The reflective electrodes 230 may be provided on the pixel array region R1 of the upper substrate 200 and may not be provided on the edge region R2. Some portions of the reflective electrodes 230 may further extend between the second bonding electrodes 250 and the upper insulating layer 211. The reflective electrodes 230 may include, but not be limited to, silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), titanium (Ti), titanium nitride (TiN), tantalum (Ta), tantalum nitride (TaN), tungsten (W), or a combination thereof.

The light emitting structure 220 may be provided on the pixel array region R1 of the upper substrate 200. The light emitting structure 220 may include a plurality of light emitting parts, and the plurality of light emitting parts may be provided in the pixel regions PX, respectively. In a plan view, the arrangement of the plurality of light emitting parts of the light emitting structure 220 may correspond to the arrangement of the pixel regions PX. The light emitting structure 220 may be disposed on the second bonding electrodes 250 and the upper insulating layer 211. The light emitting structure 220 may be electrically connected to the second bonding electrodes 250 through the reflective electrodes 230. The reflective electrodes 230 may be disposed between the plurality of light emitting parts of the light emitting structure 220 and the second bonding electrodes 250. The plurality of light emitting parts of the light emitting structure 220 may be spaced apart laterally from each other. The plurality of light emitting parts of the light emitting structure 220 may be electrically separated from each other. When the light emitting device 10 operates, the light emitting structure 220 may generate light. For example, the plurality of light emitting parts of the light emitting structure 220 may generate light. The light emitting structure 220 may not be provided on the edge region R2 of the upper substrate 200.

The light emitting structure 220 may include a first semiconductor layer 221, an active layer 223, and a second semiconductor layer 222, which are stacked in turn one on another. For example, each of the plurality of light emitting parts of the light emitting structure 220 may include corresponding portions of the first semiconductor layer 221, the active layer 223, and the second semiconductor layer 222. Each of the plurality of light emitting parts of the light emitting structure 220 may be configured to emit light in a visible light region. The light in the visible light region may have a wavelength of about 380 nanometers (nm) to about 700 nm. For example, each of the plurality of light emitting parts of the light emitting structure 220 may include a micro light emitting diode (LED), and the micro LED may generate light in a selected color (e.g., red, green, and/or blue). In the present disclosure, a micro light emitting diode may refer to an LED having a width less than or equal to about 100 micrometers (μm) in the first direction D1.

The first semiconductor layer 221 may have a first conductivity type. For example, the first semiconductor layer 221 may include a nitride semiconductor having a composition of InₓAl_{y}Ga_{1-x-y}N (where 0≤x<1, 0≤y<1, and 0≤x+y<1). As another example, the first semiconductor layer 221 may include, but not be limited to, gallium nitride (GaN) doped with p-type dopants. The p-type dopant may include, but not be limited to, magnesium (Mg), zinc (Zn), or the like. For example, the first semiconductor layer 221 may include aluminum indium gallium phosphide (AlInGaP), or aluminum indium gallium arsenide (AlInGaAs).

The second semiconductor layer 222 may be disposed on the first semiconductor layer 221. The second semiconductor layer 222 may be vertically spaced apart from the first semiconductor layer 221. The second semiconductor layer 222 may have a second conductivity type, and the second conductivity type may be different from the first conductivity type. The second semiconductor layer 222 may include a nitride semiconductor having a composition of InₓAl_{y}Ga_{1-x-y}N (where 0≤x<1, 0≤y<1, and 0≤x+y<1). The second semiconductor layer 222 may include, but not be limited to, gallium nitride (GaN) doped with n-type dopants. The n-type dopant may include, but not be limited to, silicon (Si) or the like. For example, the second semiconductor layer 222 may include aluminum indium gallium phosphide (AlInGaP), aluminum indium gallium arsenide (AlInGaAs), or the like.

The active layer 223 may be disposed between the first semiconductor layer 221 and the second semiconductor layer 222. The active layer 223 may be configured to emit light by recombination of electrons and holes. The active layer 223 may include a material having a multi-quantum well (MQW) in which a quantum well layer and a quantum barrier layer are alternately stacked. For example, the active layer 223 may include gallium nitride (GaN) and indium gallium nitride (InGaN), which may be alternately stacked. A peak wavelength of light emitted from the plurality of light emitting parts of the light emitting structure 220 may be controlled according to the material and composition of the active layer 223.

A planar shape of each of the light emitting parts of the light emitting structure 220 may vary. For example, each of the light emitting parts of the light emitting structure 220 may have a circular, elliptical, or polygonal planar shape. The polygonal shape may be a square, a hexagon, and/or an octagon, however, the present disclosure is not limited thereto. A lower portion of each of the light emitting parts of the light emitting structure 220 may protrude downward. For example, a lower portion of each of the light emitting parts of the light emitting structure 220 may protrude toward the first substrate 110. The lower portion of each of the light emitting parts of the light emitting structure 220 may include the first semiconductor layer 221 and the active layer 223. The lower portion of each of the light emitting parts of the light emitting structure 220 may further include a lower portion of the second semiconductor layer 222. The reflective layer 213 may surround sidewalls of a lower portion of each of the light emitting parts of the light emitting structure 220.

The reflective layer 213 may be provided on the pixel array region R1 of the upper substrate 200. The reflective layer 213 may be provided between the upper insulating layer 211 and the light emitting structure 220. The reflective layer 213 is provided on the bottom surface of the first semiconductor layer 221, and may cover the sidewalls of the first semiconductor layer 221 and the sidewalls of the active layer 223. The reflective layer 213 may further cover sidewalls of the lower portion of the second semiconductor layer 222. The upper portion of the second semiconductor layer 222 may be provided on the top surface of the reflective layer 213 to cover the reflective layer 213. The first semiconductor layer 221 of any one of the light emitting parts of the light emitting structure 220 may be spaced apart by the reflective layer 213 from the first semiconductor layer 221 of the other one of the light emitting parts of the light emitting structure 220 and the former may be electrically separated from the latter. The active layer 223 of any one of the light emitting parts of the light emitting structure 220 may be spaced apart by the reflective layer 213 from the active layer 223 of the other one of the light emitting parts of the light emitting structure 220 and the former may be electrically separated from the latter.

The reflective layer 213 may reflect light generated by the light emitting structure 220 to improve light extraction efficiency of the light emitting device 10. Light interference between the pixel regions PX may be further prevented/reduced by the reflective layer 213. For example, the reflective layer 213 may be a resin layer including a metal oxide. The metal oxide may include, for example, titanium oxide (TiO₂), aluminum oxide (Al₂O₃), or the like. The resin layer may include, but not be limited to, polyphthalamide (PPA). The reflective layer 213 may be and/or may include a distributed Bragg reflector (DBR) layer. The reflective layer 213 may include a plurality of insulating layers. At least two adjacent layers from among the plurality of insulating layers may have different refractive indices. The plurality of insulating layers may include, but not be limited to, an oxide (e.g., silicon oxide (SiO₂), titanium oxide (TiO₂), aluminum oxide (Al₂O₃), zirconium dioxide (ZrO₂), or the like), a nitride (e.g., silicon nitride (Si₃N₄), titanium nitride (TiN), aluminum nitride (AlN), titanium aluminum nitride (TiAlN), titanium silicon nitride (TiSiN)), and/or an oxynitride (e.g., silicon oxynitride (SiOₓN_{y})). The reflective layer 213 may have insulating characteristics.

As another example, the reflective layer 213 may include a metal layer and an insulating layer. The metal layer may include a metal material such as silver (Ag), aluminum (Al), nickel (Ni), chromium (Cr), gold (Au), platinum (Pt), palladium (Pd), tin (Sn), tungsten (W), rhodium (Rh), iridium (Ir), ruthenium (Ru), magnesium (Mg), zinc (Zn), or the like. The insulating layer is provided on the metal layer and may cover the metal layer. The insulating layer may be disposed between the metal layer and the light emitting structure 220. The insulating layer may be a transparent insulating layer. The insulating layer may include one or more of the materials described above.

As shown in FIG. 1D, the light emitting device 10 may further include transparent electrode layers 225. The transparent electrode layers 225 may be provided in the pixel regions PX, respectively. Sidewalls and bottom surfaces of the transparent electrode layers 225 may be covered by the reflective layer 213. Each of the transparent electrode layers 225 may be provided between the corresponding reflective electrode 230 and the corresponding first semiconductor layer 221. The first semiconductor layer 221 may be electrically connected to the corresponding reflective electrode 230 and the corresponding second bonding electrode 250 through the corresponding transparent electrode layer 225. For example, in a plan view, a planar shape of each of the transparent electrode layers 225 may be the same as or similar to a planar shape of a lower portion of each of the light emitting parts of the light emitting structure 220. The lower portion of any one light emitting part of the light emitting structure 220 and any one transparent electrode layer may have a single column shape. However, the shapes of the transparent electrode layers 225 are not limited thereto and may be variously modified.

The transparent electrode layers 225 may include transparent conductive oxide. For example, the transparent electrode layer may include indium tin oxide (ITO), zinc-doped indium tin oxide (ITO:Zn), indium zinc oxide (IZO), gallium indium oxide (GIO), tin zinc oxide (SnZnO₃), fluorine-doped tin oxide (SnO₂:F), aluminum-doped zinc oxide (ZnO:Al), gallium-doped zinc oxide (Ga₂ZnO₄), zinc magnesium oxide (Zn₍₁₋ₓ₎MgₓO, where 0≤x≤1), or a combination thereof.

In an embodiment, the light emitting device 10 may not include the transparent electrode layers 225. In such an embodiment, the bottom surface of the first semiconductor layer 221 may be in direct contact with the reflective layer 213. In addition, any one reflective electrode 230 may extend into the first semiconductor layer 221 and may be in direct contact with the first semiconductor layer 221.

The grid electrode 300 may be provided in the light emitting structure 220. The grid electrode 300 being provided in the light emitting structure 220 may refer to the grid electrode 300 being provided in at least one of the second semiconductor layer 222, the active layer 223, and the first semiconductor layer 221 of the light emitting structure 220. For example, the grid electrode 300 may be provided in the second semiconductor layer 222 and may penetrate the second semiconductor layer 222. The grid electrode 300 may be provided between two adjacent light emitting parts among the plurality of light emitting parts of the light emitting structure 220. The grid electrode 300 may be provided on the top surface of the reflective layer 213. Sidewalls of the second semiconductor layer 222 may be in contact with the grid electrode 300. The grid electrode 300 may be electrically connected to the second semiconductor layer 222 of the light emitting structure 220. A current may be supplied to the light emitting parts of the light emitting structure 220 through the grid electrode 300. For example, the second semiconductor layer 222 may be electrically connected to the common electrode 350 through the grid electrode 300. In particular, the second semiconductor layer 222 may be electrically connected to the common electrode 350 through the grid electrode 300 and the conductive pattern 360.

Since the grid electrode 300 is provided, the intensity of a current supplied to the light emitting parts of the light emitting structure 220 of the center portion of the pixel array region R1 of the upper substrate 200 may be substantially the same as the intensity of a current supplied to the light emitting parts of the light emitting structure 220 of the edge portion of the pixel array region R1. Accordingly, a difference between the intensity of light emitted from the light emitting parts of the light emitting structure 220 of the center portion of the pixel array region R1 of the upper substrate 200 and the intensity of light emitted from the light emitting parts of the light emitting structure 220 of the edge region R2 of the pixel array region R1 of the upper substrate 200 may be reduced. For example, the intensity of light emitted from the pixel regions PX of the center portion of the pixel array region R1 of the upper substrate 200 may be the same as and/or similar to the intensity of light emitted from the pixel regions PX of the edge portion of the pixel array region R1 of the upper substrate 200. Accordingly, a difference between the brightness of an image implemented in the center portion of the pixel array region R1 of the upper substrate 200 and the brightness of an image implemented in the edge portion of the pixel array region R1 may be reduced. Accordingly, the light emitting device 10 may implement a uniform image, thereby improving light emitting characteristics and image implementation characteristics of the light emitting device 10, when compared to a related light emitting device.

According to embodiments, the light emitting parts of the light emitting structure 220 may be spaced apart from each other by the grid electrode 300. The grid electrode 300 may include a reflective material or a light shielding material. The grid electrode 300 may improve an interference phenomenon between rays of light emitted from the plurality of light emitting parts of the light emitting structure 220 of the pixel regions PX of the upper substrate 200. A light leakage phenomenon between pixel regions PX of the upper substrate 200 may be reduced. In particular, the grid electrode 300 may prevent light emitted from the light emitting part of the light emitting structure 220 in the first pixel region among the pixel regions PX of the upper substrate 200 from being emitted to the second pixel region. For example, the second pixel region may be adjacent to the first pixel region. Accordingly, the image characteristics of the light emitting device 10 may be further improved, when further compared to a related light emitting device.

As shown in FIG. 1D, the grid electrode 300 may have a bottom surface 300b, a top surface 300a, and sidewalls 300c. A width W1 of the top surface 300a of the grid electrode 300 may be greater than a width W2 of the bottom surface 300b of the grid electrode 300. Accordingly, light extraction efficiency of light emitted from the light emitting parts of the light emitting structure 220 may be improved, when compared to a related light emitting device. The sidewalls 300c of the grid electrode 300 may be inclined sidewalls 300c. For example, the sidewalls 300c of the grid electrode 300 may be inclined with respect to the bottom surface 300b. According to embodiments, the light extraction efficiency of the light emitting device 10 may be controlled by adjusting an angle θ between the bottom surface 300b and each of the sidewalls 300c of the grid electrode 300. The angle θ between the bottom surface 300b and each of the sidewalls 300c of the grid electrode 300 may be an obtuse angle. For example, the angle θ between the bottom surface 300b and each of the sidewalls 300c of the grid electrode 300 may range from 120 degrees to 135 degrees. Since the angle θ between the bottom surface 300b and each of the sidewalls 300c of the grid electrode 300 satisfies a condition of ranging from 120 to 135 degrees, light extraction efficiency of light emitted from the plurality of light emitting parts of the light emitting structure 220 may be further improved, when compared to a related light emitting device.

The top surface 300a of the grid electrode 300 may not extend onto the top surface 220a of the light emitting structure 220. For example, the top surface 300a of the grid electrode 300 may be provided at the same level as and/or a substantially similar level to the top surface 220a of the light emitting structure 220. For example, a level difference between the top surface 220a of the light emitting structure 220 and the top surface 300a of the grid electrode 300 may be less than or equal to 250 nm. The top surface 220a of the light emitting structure 220 may correspond to the top surface of the corresponding second semiconductor layer 222. The level of any component may refer to a vertical level. The level difference between the two components may be measured in a direction parallel to the third direction D3. A thickness T1 of the grid electrode 300 may be 75% to 105% of a thickness T2 of the first portion of the light emitting structure 220. The thickness T1 of the grid electrode 300 may correspond to a distance between the top surface 300a and the bottom surface 300b of the grid electrode 300. The first portion of the light emitting structure 220 may correspond to an upper portion of the second semiconductor layer 222. The first portion of the light emitting structure 220 may not vertically overlap the active layer 223. The thickness T2 of the first portion of the light emitting structure 220 may be the same thickness and/or a substantially similar thickness as the thickness of the second semiconductor layer 222 on the top surface of the reflective layer 213.

The grid electrode 300 may include a metal material, a transparent conductive oxide, and/or a combination thereof. The metal material may include, but not be limited to, aluminum (Al), copper (Cu), gold (Au), platinum (Pt), palladium (Pd), silver (Ag), and/or alloys thereof. Example materials of the transparent conductive oxide may include materials as described in examples of transparent electrode layers 225. For example, the transparent conductive oxide may include indium tin oxide (ITO), zinc-doped indium tin oxide (ITO:Zn), indium zinc oxide (IZO), gallium indium oxide (GIO), tin zinc oxide (SnZnO₃), fluorine-doped tin oxide (SnO₂:F), aluminum-doped zinc oxide (ZnO:Al), gallium-doped zinc oxide (Ga₂ZnO₄), or a combination thereof.

The lenses 500 may be provided on the pixel regions PX of the upper substrate 200, respectively. Lenses 500 may be provided on the top surfaces 220a of the light emitting structures 220, respectively. The lenses 500 may include one or more microlenses. The lenses 500 may cover the light emitting parts of the light emitting structure 220, respectively The lenses 500 may be configured to extract light emitted from the light emitting parts of the light emitting structure 220. The lenses 500 may vertically overlap the light emitting parts of the light emitting structure 220. The bottom surfaces of the lenses 500 may face the second semiconductor layers 222, respectively. The top surfaces of the lenses 500 may face the bottom surfaces. The top surfaces of the lenses 500 may have an upwardly convex shape. For example, the top surfaces of the lenses 500 may have a hemispherical shape or a shape similar to a hemispherical shape. The lenses 500 may include an organic material or an inorganic material. The organic material may include, for example, a photoresist material. The inorganic material may include oxides. The inorganic material may be and/or may include, for example, titanium oxide (TiO₂), silicon carbide (SiC), gallium nitride (GaN), gallium phosphide (GaP), silicon nitride (Si₃N₄), silicon oxynitride (SiOₓN_{y}), zirconium dioxide (ZrO₂), indium tin oxide (ITO), aluminum nitride (AlN), aluminum oxide (Al₂O₃), MgO, silicon oxide (SiO₂), calcium fluoride (CaF₂), magnesium fluoride (MgF₂), or a combination thereof. However, the present disclosure is not limited thereto.

Each of the lenses 500 may be a single layer or multiple layers. For example, the lenses 500 may include a graded-refractive index layer formed in a multilayer structure in which the refractive index gradually decreases in a direction in which light propagates. The refractive indices of the lenses 500 may be greater than the refractive index of air. For example, the refractive index of the lenses 500 may be greater than one (1). Since the light emitting device 10 includes the lenses 500, the light extraction efficiency of the light emitting device 10 may be improved, when compared to a related light emitting device.

The width of each of the lenses 500 may be equal to or greater than the width of the lower portion of the corresponding light emitting part of the light emitting structure 220. For example, the width of each of the lenses 500 may be equal to or greater than the width of the corresponding first semiconductor layer 221 and the width of the corresponding active layer 223.

According to embodiments, since the top surface 300a of the grid electrode 300 is provided at the same or similar level as the top surface 220a of the light emitting structure 220, the lenses 500 may be easily formed. For example, since the thickness T1 of the grid electrode 300 is 75% to 105% of the thickness T2 of the first portion of the light emitting structure 220, the lenses 500 may be formed more easily. Since the difference in level between the top surface 220a of the light emitting structure 220 and the top surface 300a of the grid electrode 300 is less than or equal to 250 nm, the lenses 500 may be formed more easily.

The reflective electrodes 230, the first semiconductor layers 221, the active layers 223, the grid electrodes 300, and the lenses 500 are provided on the pixel array region R1 of the upper substrate 200, but may be spaced apart from the edge region R2 of the upper substrate 200. The reflective layer 213 and the second semiconductor layer 222 may further extend onto the edge region R2 of the upper substrate 200. In an embodiment, the reflective layer 213 and the second semiconductor layer 222 may not further extend onto the edge region R2 of the upper substrate 200.

Hereinafter, configurations on and within the edge region R2 of the upper substrate 200 are described.

As shown in FIGS. 1B and 1C, the upper substrate 200 may further include the pad electrode 265 and the bonding pad 275. The pad electrode 265 may be provided in the upper insulating layer 211. The second bonding electrodes 250 may further extend from the second bonding insulating layer 240 into the upper insulating layer 211. The pad electrode 265 may be provided on the top surface of the at least one of the second bonding electrodes 250 to be electrically connected to the at least one second bonding electrode 250. The pad electrode 265 may include a conductive material such as metal. For example, the pad electrode 265 may include, but not be limited to, silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), or a combination thereof.

The bonding pad 275 may be provided on the pad electrode 265 to be electrically connected to the pad electrode 265. The bonding pad 275 may be electrically connected to the corresponding second bonding electrode 250 through the pad electrode 265. The bonding pad 275 may be electrically connected to an external device through connection parts. The connection parts may include wire bonding and/or an anisotropic conductive film (ACF). An electrical signal of an external device may be transmitted to the plurality of transistors 115 of the lower substrate 100 through the bonding pad 275. The bonding pad 275 may include a conductive material such as, but not limited to, a metal, or the like. For example, the bonding pad 275 may include, but not be limited to, gold (Au), silver (Ag), nickel (Ni), or the like.

The light emitting device 10 may further include a common electrode 350. The common electrode 350 may be provided on the edge region R2 of the upper substrate 200. The common electrode 350 may be provided in the upper insulating layer 211. The top surface of the common electrode 350 may be exposed by the upper insulating layer 211. The common electrode 350 may be disposed on a plurality of second bonding electrodes 250 to be electrically connected to the plurality of second bonding electrodes 250. Accordingly, the common electrode 350 may be electrically connected to the wiring line 130 through the plurality of second bonding electrodes 250, the corresponding first bonding electrodes 150, and at least one conductive line 135. A current may be supplied to the common electrode 350 through the wiring line 130, at least one conductive line 135, the first bonding electrodes 150, and the second bonding electrodes 250.

The common electrode 350 may include a conductive material such as, but not limited to, a metal, or the like. For example, the common electrode 350 may include, but not be limited to, silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), or a combination thereof. The common electrode 350 may include the same metal as the pad electrode 265. However, the present disclosure is not limited thereto.

The conductive pattern 360 may cover a top surface of the common electrode 350. The conductive pattern 360 may be electrically connected to the common electrode 350. The conductive pattern 360 may extend onto the pixel array region R1 of the upper substrate 200 to cover a top surface of an outer portion of the grid electrode 300. The conductive pattern 360 may be in contact with the top surface of the outer portion of the grid electrode 300. Accordingly, the conductive pattern 360 may be electrically connected to the grid electrode 300. According to embodiments, the current supplied through the common electrode 350 may be transmitted to the grid electrode 300 through the conductive pattern 360. The grid electrode 300 may uniformly supply current to the center portion and the edge portion of the pixel array region R1 of the upper substrate 200.

The conductive pattern 360 may not extend onto bottom surfaces or top surfaces of the lenses 500. For example, the conductive pattern 360 may be spaced apart from the lenses 500. The conductive pattern 360 may include, for example, a metal.

Hereinafter, the arrangement of the pixel regions PX and the arrangement of the grid electrode 300, according to embodiments, are described.

Referring to FIG. 1E together with FIGS. 1A to 1D, the pixel regions PX may be arranged two-dimensionally (2D) in the row direction and the column direction in a plan view. The row direction may be parallel to the first direction D1. The column direction may be parallel to the second direction D2. The grid electrode 300 may be disposed between the pixel regions PX.

The pixel regions PX may include first sub-pixels PX1, second sub-pixels PX2, and third sub-pixels PX3. Light emitting parts of the light emitting structure 220 may be provided on the first to third sub-pixels PX1 to PX3, respectively. Each of the components on the first to third sub-pixels PX1 to PX3 may be configured to emit light of one or more colors. For example, the light emitting parts of the light emitting structure 220 on the first to third sub-pixels PX1 to PX3 may be configured to emit green light, red light, and blue light, respectively. However, the present disclosure is not limited in this regard, and the first to third sub-pixels PX1 to PX3 may emit the same or other colors. The first sub-pixels PX1 may be green sub-pixels. In particular, when the light emitting parts of the light emitting structure 220 are provided on the first sub-pixels PX1, the light emitting parts of the light emitting structure 220 may emit light corresponding to green light. The second sub-pixels PX2 may be red sub-pixels, and the third sub-pixels PX3 may include blue sub-pixels. When the light emitting parts of the light emitting structure 220 are provided on the second sub-pixels PX2, the light emitting parts of the light emitting structure 220 may emit light corresponding to red light. When the light emitting parts of the light emitting structure 220 are provided on the first sub-pixels PX1, the light emitting parts of the light emitting structure 220 may emit light corresponding to blue light.

The sub-pixels may be arranged according to a Bayer pattern. The first sub-pixels PX1 may be arranged in a fourth direction D4. Each of the second sub-pixels PX2 may be disposed between two adjacent first sub-pixels PX1. Each of the third sub-pixels PX3 may be disposed between two adjacent first sub-pixels PX1. The third sub-pixels PX3 may be arranged with the second sub-pixels PX2 in a fifth direction D5. The fourth direction D4 may be parallel to the bottom surface of the first substrate 110 and may intersect the first and second directions D1 and D2. The fifth direction D5 may be parallel to the bottom surface of the first substrate 110 and may intersect the first, second, and fourth directions D1, D2, and D4. For example, the fifth direction D5 may be substantially perpendicular to the fourth direction D4. However, the present disclosure is not limited thereto.

For example, the number of first sub-pixels PX1 may be greater than the number of second sub-pixels PX2. For example, the number of the first sub-pixels PX1 may be greater than or equal to twice the number of the second sub-pixels PX2. The number of first sub-pixels PX1 may be greater than the number of third sub-pixels PX3. For example, the number of the first sub-pixels PX1 may be greater than or equal to twice the number of the third sub-pixels PX3.

Although the first to third sub-pixels PX1 to PX3 in FIG. 1E are arranged in a 2×2 Bayer pattern, the present disclosure is not limited thereto. For example, each of the plurality of pixel regions PX may be configured in a different arrangement such as, but not limited to, 3×3 or 4×4. In an embodiment, the pixel regions PX may have an arrangement of, for example, 1,024×768. The arrangement and number of pixel regions PX may be variously modified. In other examples, some of the plurality of pixel regions PX may be configured to emit a color different from that of red (R), green (G), and blue (B), such as yellow light.

FIG. 1F illustrates a cross-sectional view taken along the line III-III′ of FIG. 1B and a cross-sectional view taken along the line IV-IV′ of FIG. 1B, according to embodiments. FIG. 1G is an enlarged view of a region V of FIG. 1C, according to embodiments. The light emitting device 10AA of FIGS. 1F and 1G may include and/or may be similar in many respects to the light emitting device 10 described above with reference to FIGS. 1A to 1E and may include additional features not mentioned above. Consequently, repeated descriptions of the light emitting device 10AA described above with reference to FIGS. 1A to 1E may be omitted for the sake of brevity.

Referring to FIGS. 1F and 1G, the light emitting device 10AA may include a lower substrate 100, an upper substrate 200, a grid electrode 300, and lenses 500.

The grid electrode 300 may be provided in the light emitting structure 220. The grid electrode 300 provided in the light emitting structure 220 may include the grid electrode 300 provided in a part of the second semiconductor layer 222. For example, the grid electrode 300 may be provided in an upper portion of the second semiconductor layer 222 and may penetrate the upper portion of the second semiconductor layer 222. The grid electrode 300 may not penetrate the lower portion of the second semiconductor layer 222. The bottom surface 300b of the grid electrode 300 may be provided in the second semiconductor layer 222. The top surface 300a of the grid electrode 300 may be provided at the same level as or at substantially similar level to the top surface 220a of the light emitting structure 220. For example, a level difference between the top surface 220a of the light emitting structure 220 and the top surface 300a of the grid electrode 300 may be less than or equal to 250 nm.

The light emitting device 10AA may not include the conductive pattern 360 of FIG. 1C. The grid electrode 300 may further extend onto the edge region R2 of the upper substrate 200 to be electrically connected to the common electrode 350. For example, the grid electrode 300 may be directly electrically connected to the common electrode 350. Accordingly, the second semiconductor layer 222 may be electrically connected to the common electrode 350 through the grid electrode 300.

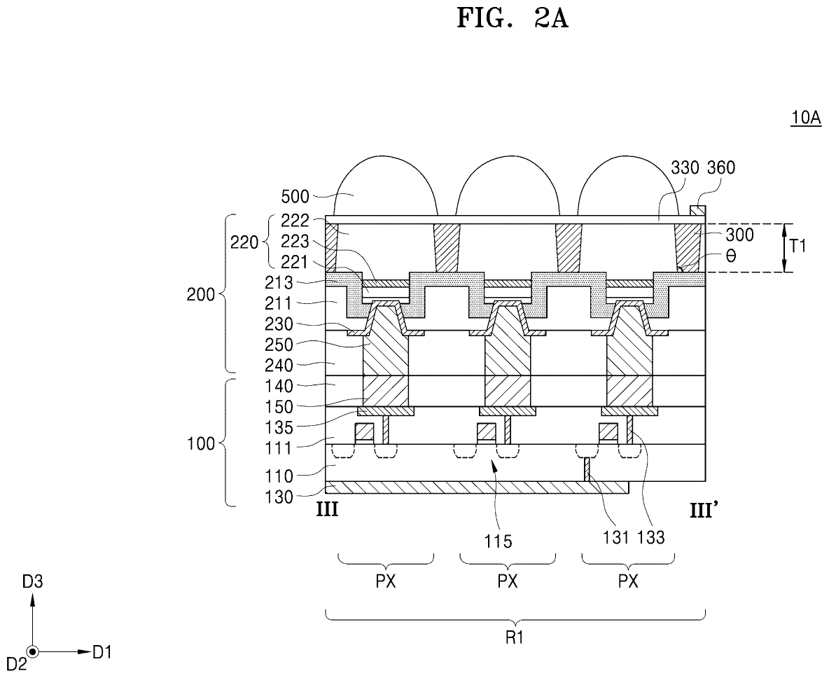

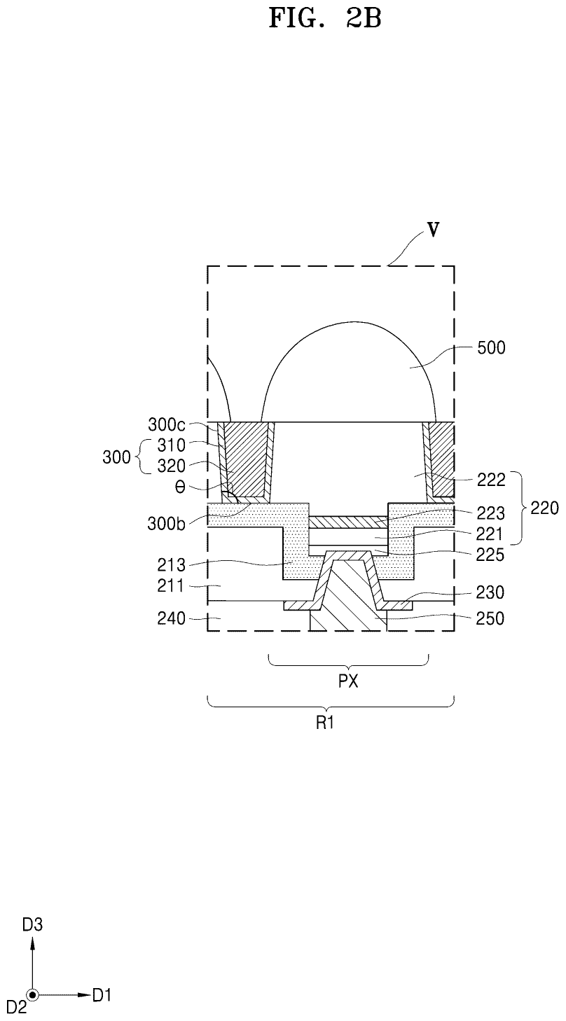

FIG. 2A is a cross-sectional view to describe a light emitting device, according to embodiments, which corresponds to a cross-section taken along a line III-III′ of FIG. 1B, according to embodiments. The description of FIG. 2A is made with reference to FIGS. 1B and 1C together. The light emitting device 10A of FIGS. 2A and 2B may include and/or may be similar in many respects to the light emitting device 10 described above with reference to FIGS. 1A to 1E and may include additional features not mentioned above. Consequently, repeated descriptions of the light emitting device 10A described above with reference to FIGS. 1A to 1E may be omitted for the sake of brevity.

Referring to FIG. 2A, the light emitting device 10A may further include a transparent conductive layer 330 in addition to the lower substrate 100, the upper substrate 200, the grid electrode 300, and the lenses 500. The transparent conductive layer 330 may be provided on the top surface of the light emitting structure 220 and the top surface of the grid electrode 300. The lenses 500 may be provided on the transparent conductive layer 330. The refractive index of the transparent conductive layer 330 may be different from those of the second semiconductor layer 222 and the lenses 500. For example, the refractive index of the transparent conductive layer 330 may be greater than the refractive index of the second semiconductor layer 222 and less than the refractive indices of the lenses 500. The transparent conductive layer 330 may include a transparent conductive oxide. The thickness of the transparent conductive layer 330 may be less than the thickness T1 of the grid electrode 300.

The conductive pattern 360 may be provided on the transparent conductive layer 330. The grid electrode 300 may be electrically connected to the common electrode 350 of FIG. 1C through the conductive pattern 360. The configurations on the edge region R2 of the upper substrate 200 may include or may be similar in many respects to those described with reference to FIGS. 1B and 1C.

FIG. 2B is a cross-sectional view to describe a grid electrode, according to embodiments, and corresponds to an enlarged view of a region V of FIG. 1C, according to embodiments.

Referring to FIG. 2B, the grid electrode 300 may include a seed pattern 310 and a conductive electrode 320. The seed pattern 310 may cover sidewalls and a bottom surface of the conductive electrode 320. For example, the seed pattern 310 may be disposed between the conductive electrode 320 and the reflective layer 213 and between the conductive electrode 320 and the light emitting structure 220. The seed pattern 310 may not extend onto the top surface of the conductive electrode 320. The thickness of the seed pattern 310 may be less than the thickness of the conductive electrode 320. The seed pattern 310 may include a conductive seed material such as, but not limited to, titanium (Ti) and/or titanium copper (TiCu), for example. The bottom surface 300b of the grid electrode 300 may correspond to the bottom surface of the seed pattern 310, and the sidewalls 300c of the grid electrode 300 may correspond to the outer walls of the seed pattern 310.

In an embodiment, the seed pattern 310 may not extend onto the sidewalls of the conductive electrode 320. For example, the seed pattern 310 may not be disposed between the conductive electrode 320 and the light emitting structure 220.

The conductive electrode 320 may be provided on the seed pattern 310. The conductive electrode 320 may be formed by a plating process using the seed pattern 310 as an electrode. The conductive electrode 320 may include a metal material, a transparent conductive oxide, and/or a combination thereof. The metal material may include, but not be limited to, aluminum (Al), copper (Cu), gold (Au), platinum (Pt), palladium (Pd), silver (Ag), and/or alloys thereof.

In an embodiment, the grid electrode 300 may not include the seed pattern 310.

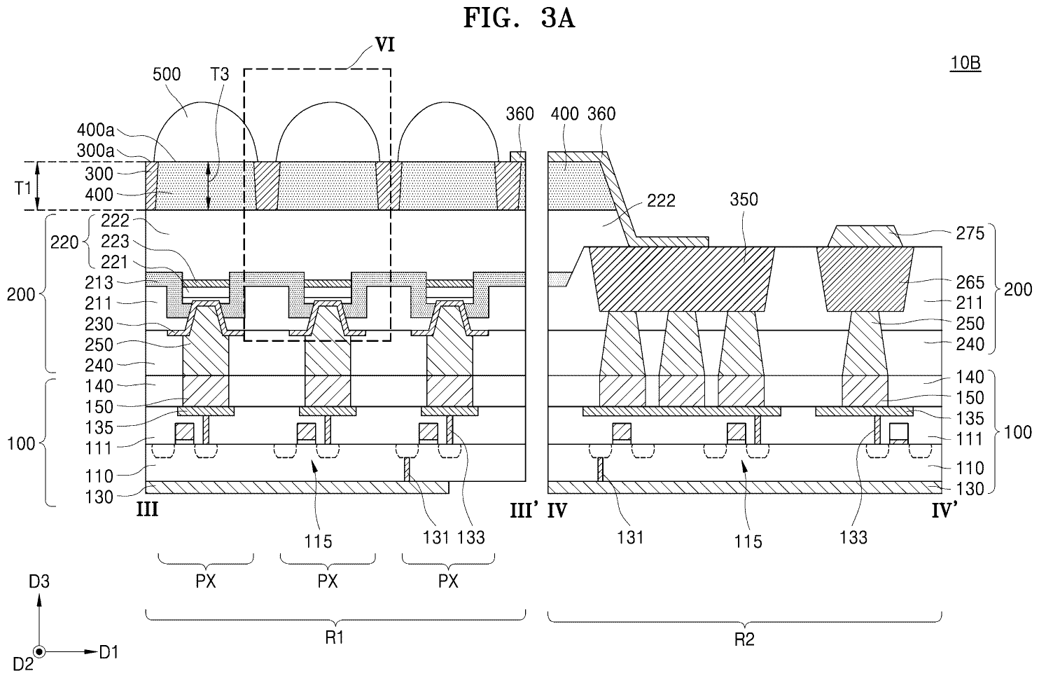

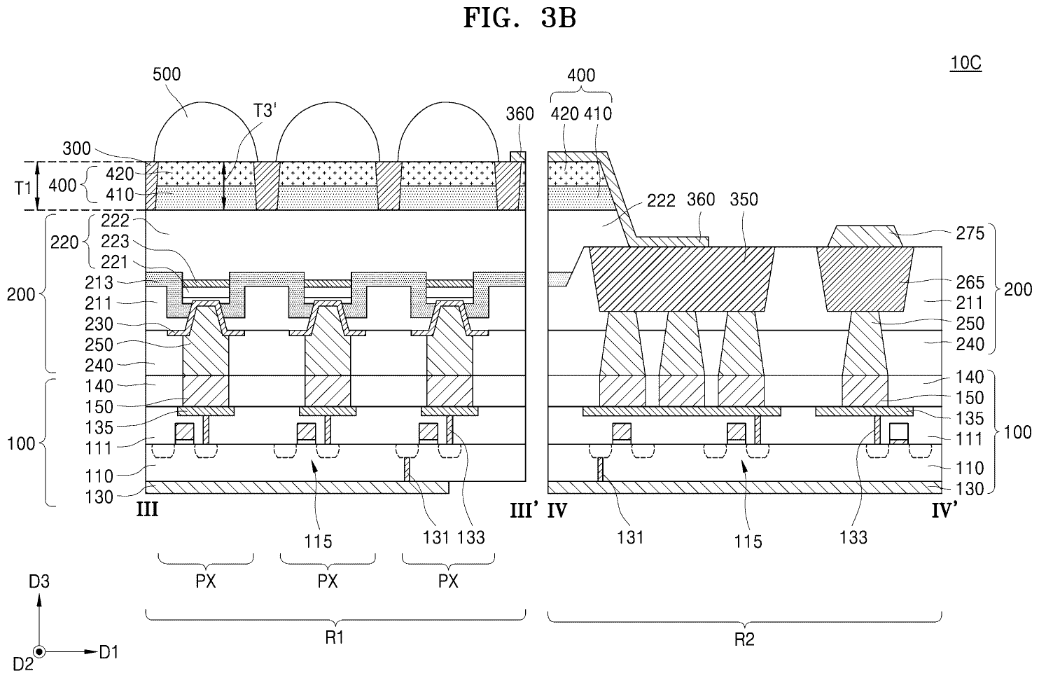

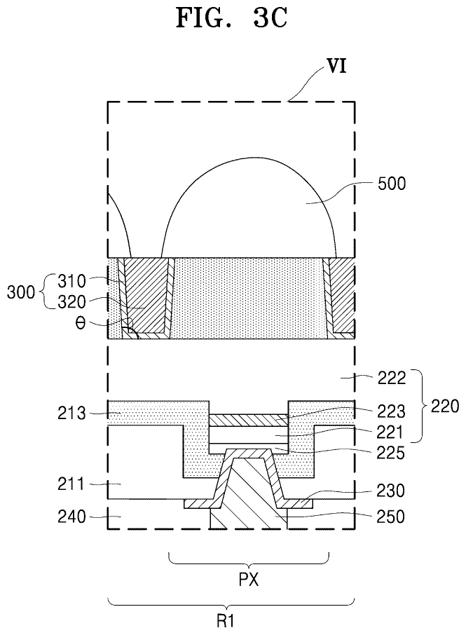

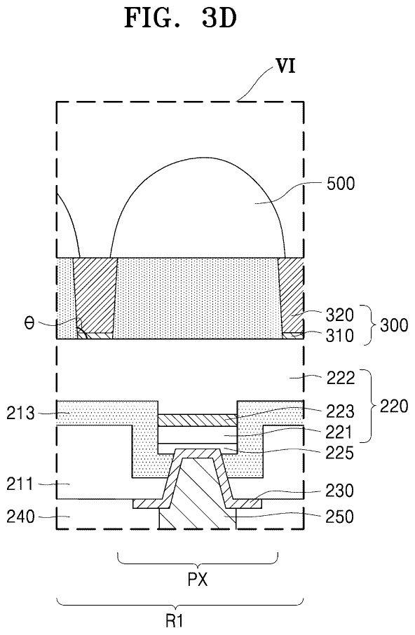

FIG. 3A illustrates views of a light emitting device, according to embodiments, and corresponds to a cross-sectional view taken along line III-III′ of FIG. 1B and a cross-sectional view taken along line IV-IV′ of FIG. 1B. Hereinafter, the description of FIG. 3A is made together with reference to FIG. 1B. The light emitting device 10B of FIG. 3A may include and/or may be similar in many respects to the light emitting device 10 described above with reference to FIGS. 1A to 1E and may include additional features not mentioned above. Consequently, repeated descriptions of the light emitting device 10B described above with reference to FIGS. 1A to 1E may be omitted for the sake of brevity.

Referring to FIG. 3A, a light emitting device 10B may include a passivation layer 400 in addition to the lower substrate 100, the upper substrate 200, the grid electrode 300, the conductive pattern 360, the common electrode 350, and the lenses 500.

The light emitting structure 220 may be provided on the top surface of the reflective layer 213. The light emitting structure 220 may include a plurality of first semiconductor layers 221, a plurality of active layers 223, and a second semiconductor layer 222. The plurality of first semiconductor layers 221 and the plurality of active layers 223 may be substantially the same as described in the examples of FIG. 1C. The second semiconductor layer 222 is provided on the plurality of active layers 223, and may extend onto a top surface of the reflective layer 213. A plurality of pixel regions PX may share the second semiconductor layer 222.

The passivation layer 400 may be disposed on the top surface of the light emitting structure 220. The passivation layer 400 may cover a top surface of the second semiconductor layer 222. The passivation layer 400 may be provided between the light emitting structure 220 and the lenses 500. The passivation layer 400 may transmit light generated from the light emitting structure 220. The passivation layer 400 may include an insulating material. For example, the passivation layer 400 may include a transparent insulating material. The passivation layer 400 may include a silicon-containing insulating material. The silicon-containing insulating material may be and/or may include, but not be limited to, silicon oxide (SiO₂), silicon nitride (Si₃N₄), silicon oxynitride (SiOₓN_{y}), silicon carbide nitride (SiCN), silicon carbide oxide (SiCO), or the like. The silicon-containing insulating material may further include silicon carbide oxynitride (SiCON). The passivation layer 400 may include, for example, aluminum oxide (Al₂O₃).

The grid electrode 300 may be provided between the pixel regions PX in a plan view as described with reference to FIGS. 1B and 1E. However, unlike FIG. 1C, the grid electrode 300 may be provided on the top surface of the light emitting structure 220 and in the passivation layer 400. The grid electrode 300 may penetrate the passivation layer 400. The grid electrode 300 may be provided on the top surface of the second semiconductor layer 222 and may be in contact with the top surface of the second semiconductor layer 222. The sidewalls 300c of the grid electrode 300 may be inclined sidewalls. An angle between the bottom surface and each of the sidewalls of the grid electrode 300 may be an obtuse angle. For example, the angle between the bottom surface and each of the sidewalls of the grid electrode 300 may be 120 degrees to 135 degrees. Accordingly, light extraction efficiency of light emitted from the light emitting structure 220 may be further improved, when compared to a related light emitting device.

The refractive index of the passivation layer 400 may be lower than the refractive index of the second semiconductor layer 222 and higher than the refractive indices of the lenses 500. Accordingly, the light extraction efficiency of the light emitting device 10B may be improved, when compared to a related light emitting device.

The top surface 300a of the grid electrode 300 may not extend onto the top surface 400a of the passivation layer 400. The top surface 300a of the grid electrode 300 may be provided at substantially the same level as or similar to the top surface 400a of the passivation layer 400. For example, a thickness T1 of the grid electrode 300 may be 75% to 105% of a thickness T3 of the passivation layer 400. A level difference between the top surface 400a of the passivation layer 400 and the top surface 300a of the grid electrode 300 may be less than or equal to 250 nm

The lenses 500 may be provided on the top surface 400a of the passivation layer 400. Light emitted from the light emitting structure 220 may be transmitted to the lenses 500 through the passivation layer 400. The lenses 500 may be configured to extract light emitted from the light emitting structure 220. At least one of the lenses 500 may extend onto the top surface 300a of the grid electrode 300 to further cover the top surface 300a of the grid electrode 300. According to embodiments, since a level difference between the top surface 300a of the grid electrode 300 and the top surface 400a of the passivation layer 400 is reduced, the lenses 500 may be easily formed on the top surface 300a of the grid electrode 300 and the top surface 400a of the passivation layer 400. For example, since the thickness T1 of the grid electrode 300 is 75% to 105% of the thickness T3 of the passivation layer 400, the lenses 500 may be formed more easily. Since a level difference between the top surface 400a of the passivation layer 400 and the top surface 300a of the grid electrode 300 is less than or equal to 250 nm, the lenses 500 may be formed more easily.

The conductive pattern 360 may cover a top surface of an outer portion of the grid electrode 300 and a top surface of the common electrode 350. According to embodiments, the current supplied through the common electrode 350 may be transmitted to the grid electrode 300 through the conductive pattern 360. The grid electrode 300 may be electrically connected to the light emitting structure 220. For example, the grid electrode 300 may be electrically connected to the second semiconductor layer 222. Accordingly, a difference between the brightness of an image implemented in the edge portion of the pixel array region R1 of the light emitting device 10B and the brightness of an image implemented in the center portion of the pixel array region R1 may be reduced. The light emitting device 10B may implement a more uniform image, when compared to a related light emitting device.

The passivation layer 400 may further extend onto the edge region R2 of the upper substrate 200 to be further disposed between a part of the common electrode 350 and a part of the conductive pattern 360. Alternatively or additionally, the passivation layer 400 may not extend between the common electrode 350 and the conductive pattern 360.

FIG. 3B illustrates views of a light emitting device, according to embodiments, and corresponds to a cross-sectional view taken along line III-III′ of FIG. 1B and a cross-sectional view taken along line IV-IV′ of FIG. 1B, according to embodiments. The light emitting device 10C of FIG. 3B may include and/or may be similar in many respects to the light emitting device 10 described above with reference to FIGS. 1A to 1E and may include additional features not mentioned above. Consequently, repeated descriptions of the light emitting device 10C described above with reference to FIGS. 1A to 1E may be omitted for the sake of brevity.

Referring to FIG. 3B together with FIG. 1B, the light emitting device 10C may include a lower substrate 100, an upper substrate 200, a grid electrode 300, a passivation layer 400, a conductive pattern 360, a common electrode 350, and lenses 500. The passivation layer 400 may include a first passivation layer 410 and a second passivation layer 420. The first passivation layer 410 may be disposed on the light emitting structure 220 to cover a top surface of the second semiconductor layer 222. The refractive index of the first passivation layer 410 may be lower than the refractive index of the second semiconductor layer 222 and higher than the refractive indices of the lenses 500. The first passivation layer 410 may include a transparent insulating material. The material of the first passivation layer 410 may be the same as described in the example of the passivation layer 400 of FIG. 3A.

The second passivation layer 420 may be provided on the first passivation layer 410. The refractive index of the second passivation layer 420 may be lower than the refractive index of the first passivation layer 410 and higher than the refractive indices of the lenses 500. The second passivation layer 420 may include a transparent insulating material. The material of the second passivation layer 420 may be the same as described in the example of the passivation layer 400 of FIG. 3A. However, the second passivation layer 420 may include an insulating material different from that of the first passivation layer 410. The top surface of the passivation layer 400 may include the top surface of the second passivation layer 420.

The grid electrode 300 may be provided in the passivation layer 400. The grid electrode 300 may penetrate the first passivation layer 410 and the second passivation layer 420. The top surface of the grid electrode 300 may be provided at substantially the same level as or similar to the top surface of the passivation layer 400. For example, a thickness T1 of the grid electrode 300 may be 75% to 105% of a thickness T3′ of the passivation layer 400. The thickness T3′ of the passivation layer 400 may be substantially the same as the sum of the thicknesses of the first passivation layer 410 and the thickness of the second passivation layer 420. A level difference between the top surface of the passivation layer 400 and the top surface of the grid electrode 300 may be less than or equal to 250 nm. Accordingly, the lenses 500 may be easily formed on the top surface of the passivation layer 400.

The number of stacked layers of the passivation layer 400 may be variously modified without being limited as illustrated. In an embodiment, the passivation layer 400 may further include a third passivation layer. In such an embodiment, the third passivation layer may be provided between the first passivation layer 410 and the second passivation layer 420. The refractive index of the third passivation layer may be lower than the refractive index of the first passivation layer 410 and higher than the refractive index of the second passivation layer 420.

FIG. 3C is a cross-sectional view to describe a grid electrode, according to embodiments, and corresponds to an enlarged view of a region VI of FIG. 3A, according to embodiments.

Referring to FIG. 3C, the grid electrode 300 may include a seed pattern 310 and a conductive electrode 320. The seed pattern 310 may cover sidewalls and a bottom surface of the conductive electrode 320. For example, the seed pattern 310 may be disposed between the conductive electrode 320 and the light emitting structure 220 and between the conductive electrode 320 and the passivation layer 400. The seed pattern 310 may not extend onto the top surface of the conductive electrode 320. The seed pattern 310 and the conductive electrode 320 may be the same as or similar to those described in the example of FIG. 2B. In an embodiment, the grid electrode 300 may not include the seed pattern 310.

FIG. 3D is a cross-sectional view to describe a grid electrode, according to embodiments, and corresponds to an enlarged view of the region VI of FIG. 3A.

Referring to FIG. 3D, the grid electrode 300 may include the seed pattern 310 and the conductive electrode 320. The seed pattern 310 may cover a bottom surface of the conductive electrode 320 but may not extend onto sidewalls of the conductive electrode 320. For example, the seed pattern 310 may be disposed between the conductive electrode 320 and the light emitting structure 220. The passivation layer 400 may cover the sidewalls of the conductive electrode 320.

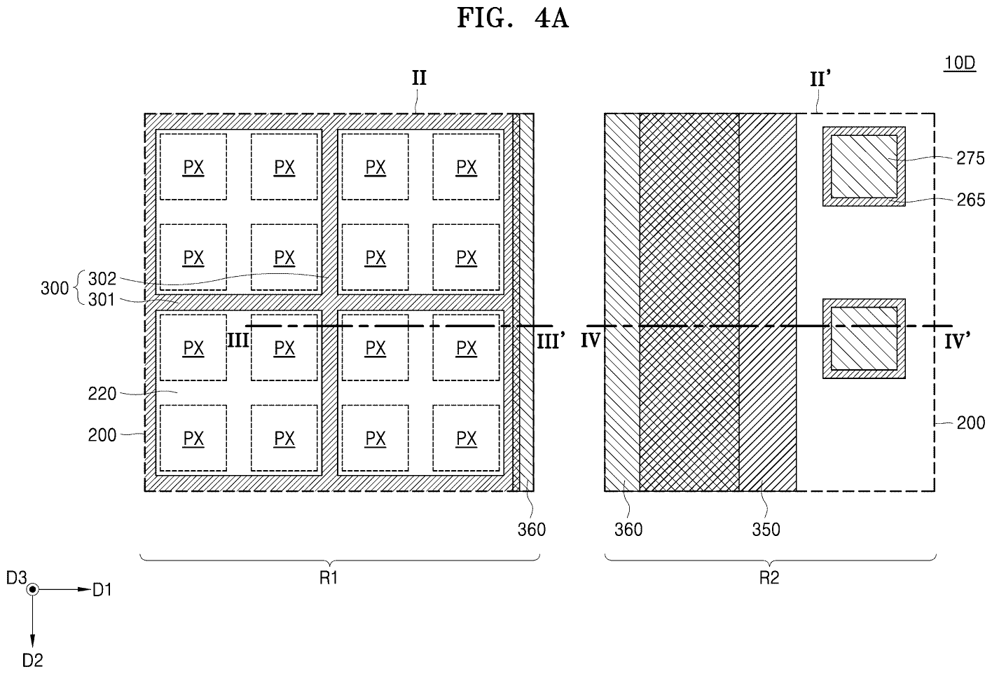

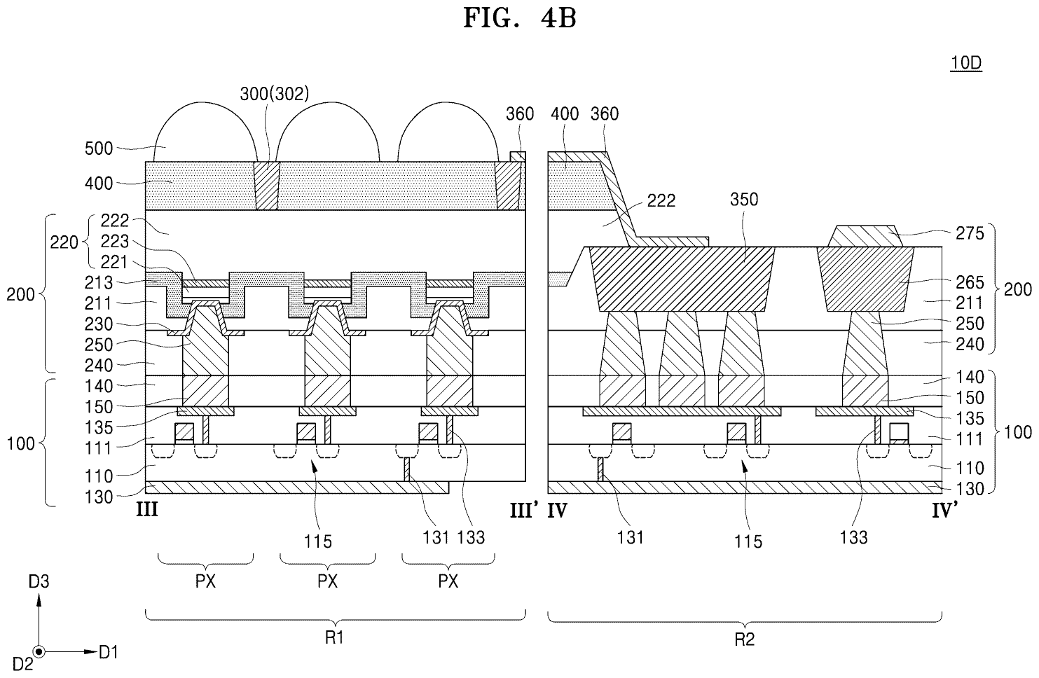

FIG. 4A illustrates plan views to describe a light emitting device, according to embodiments, and corresponds to a plan view in which a region II of FIG. 1A is enlarged and a plan view in which a region II′ is enlarged, according to embodiments. FIG. 4B illustrates a cross-sectional view taken along the line III-III′ of FIG. 4A and a cross-sectional view taken along the line IV-IV′ of FIG. 4A, according to embodiments. The light emitting device 10D of FIGS. 4A and 4B may include and/or may be similar in many respects to the light emitting device 10 described above with reference to FIGS. 1A to 1E and may include additional features not mentioned above. Consequently, repeated descriptions of the light emitting device 10D described above with reference to FIGS. 1A to 1E may be omitted for the sake of brevity.

Referring to FIGS. 4A and 4B, the light emitting device 10D may include a lower substrate 100, an upper substrate 200, a grid electrode 300, a conductive pattern 360, a common electrode 350, a passivation layer 400, and lenses 500.

The grid electrode 300 may be provided between any two adjacent pixel regions PX among the pixel regions PX of the upper substrate 200. However, the grid electrode 300 may not be provided between the other two adjacent pixel regions PX among the pixel regions PX. At least two pixel regions PX may be provided between the adjacent second portions 302 of the grid electrode 300. An interval between the second portions 302 of the grid electrode 300 may be increased. As shown in FIG. 4A, at least two pixel regions PX may be provided between the adjacent first portions 301 of the grid electrode 300. An interval between the first portions 301 of the grid electrode 300 may be increased. Accordingly, light extraction efficiency of light emitted from the light emitting structure 220 may be increased.

The number of pixel regions PX provided between the second portions 302 of the grid electrode 300 may be variously modified. Likewise, the number of pixel regions PX provided between the first portions 301 of the grid electrode 300 may be variously modified.

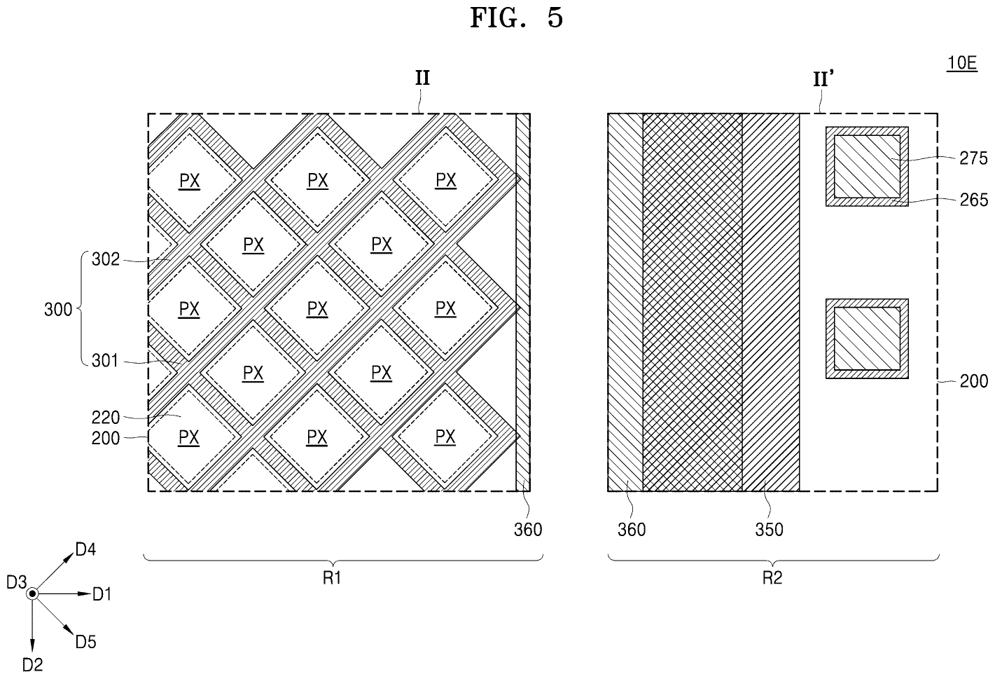

FIG. 5 illustrates plan views to describe an arrangement of a grid electrode, according to embodiments, and corresponds to a plan view in which the region II of FIG. 1A is enlarged and a plan view in which the region II′ is enlarged, according to embodiments. The light emitting device 10E of FIG. 5 may include and/or may be similar in many respects to the light emitting device 10 described above with reference to FIGS. 1A to 1E and may include additional features not mentioned above. Consequently, repeated descriptions of the light emitting device 10E described above with reference to FIGS. 1A to 1E may be omitted for the sake of brevity.

Referring to FIG. 5, the pixel array region R1 of the upper substrate 200 may include a plurality of pixel regions PX. The pixel regions PX may be arranged in a pantile manner.

The grid electrode 300 may be disposed between the pixel regions PX. The grid electrode 300 may include first portions 301 and second portions 302. The first portions 301 may extend in a direction parallel to the fourth direction D4 and may be spaced apart from each other in the fifth direction D5. The second portions 302 may extend in a direction parallel to the fifth direction D5 and may be spaced apart from each other in the fourth direction D4. The second portions 302 may be connected to the first portions 301.

Embodiments of the present disclosure may be combined with each other. For example, at least two of the embodiments of FIGS. 1A to 1E, the embodiments of FIGS. 1F and 1G, the embodiments of FIG. 2A, the embodiments of FIG. 2B, the embodiments of FIG. 3A, the embodiments of FIG. 3B, the embodiments of FIG. 3C, the embodiments of FIG. 3D, the embodiments of FIGS. 4A and 4B, and the embodiments of FIG. 5 may be combined. For example, the light emitting device 10B of FIG. 3A, the light emitting device 10C of FIG. 3B, or the light emitting device 10D of FIGS. 4A and 4B may further include the transparent conductive layer 330 as shown in FIG. 2A.

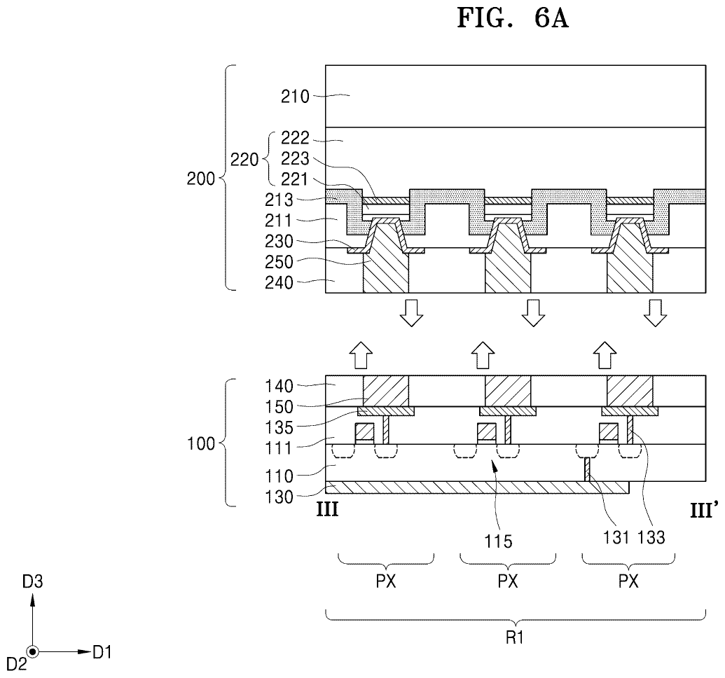

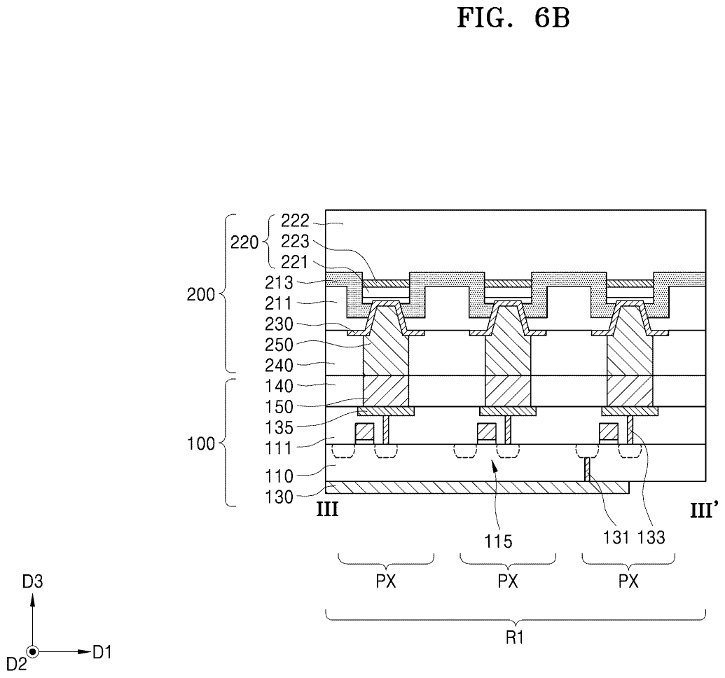

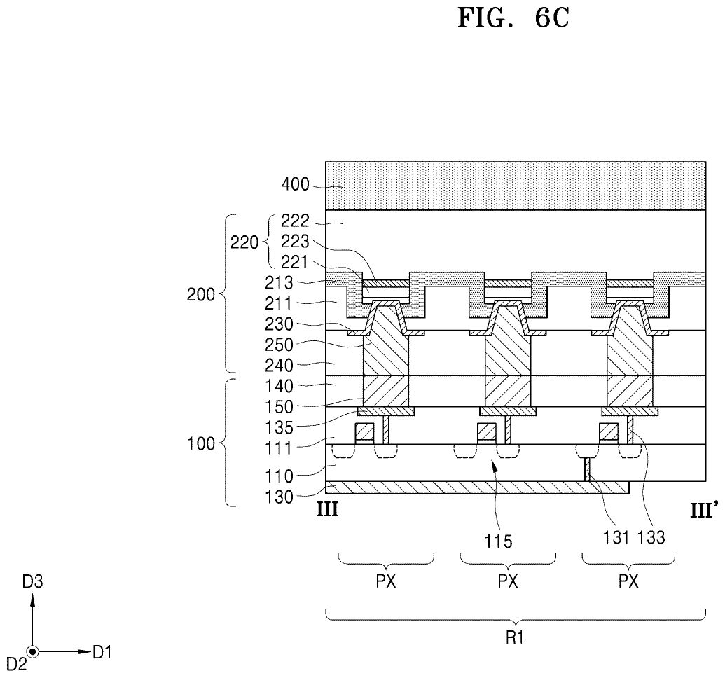

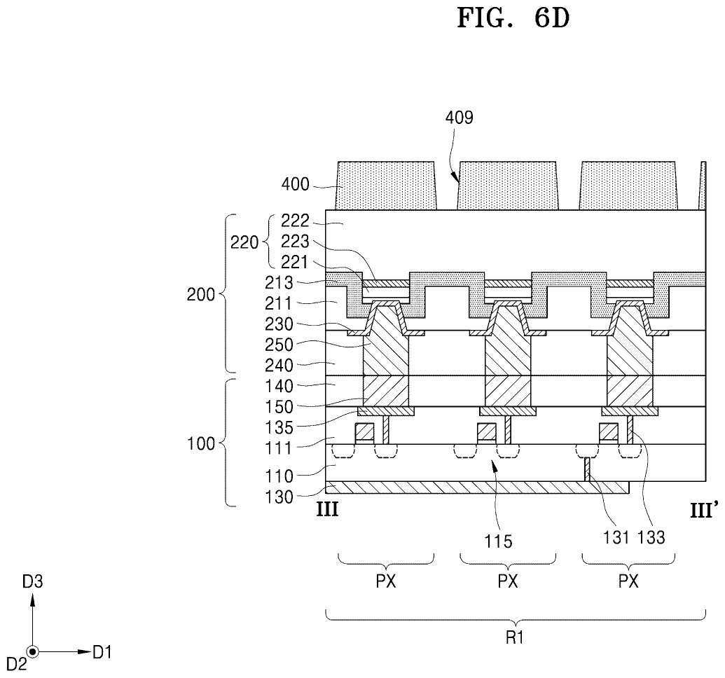

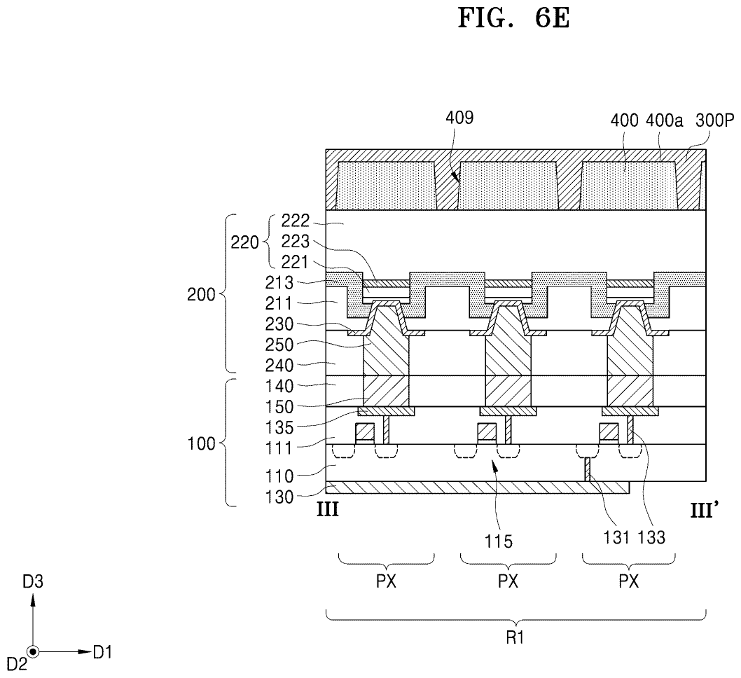

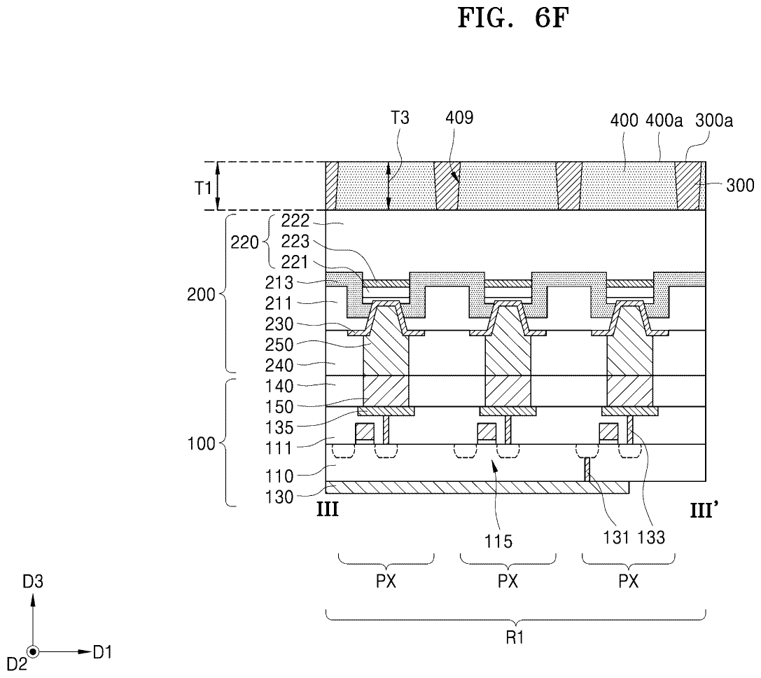

FIGS. 6A to 6F are views illustrating a method of manufacturing a light emitting device, according to embodiments, and correspond to cross-sections taken along a line III-III′ of FIG. 1B. In the description of FIGS. 6A to 6F, manufacturing of components corresponding to the pixel array region of the upper substrate is described for simplicity. The description of FIGS. 6A to 6F is made together with reference to FIG. 1B. For simplification, a single active layer and a single first semiconductor layer are described. In addition, repeated descriptions of the light emitting device depicted in FIGS. 6A to 6F described above with reference to FIGS. 1A to 5 may be omitted for the sake of brevity.

Referring to FIG. 6A, a lower substrate 100 and an upper substrate 200 may be prepared. Forming the lower substrate 100 may include forming the plurality of transistors 115, the lower insulating layer 111, the upper vias 133, the conductive lines 135, the first bonding insulating layer 140, and the first bonding electrodes 150 on the top surface of the first substrate 110. The forming of the lower substrate 100 may further include forming the lower vias 131 in the first substrate 110 and forming the wiring line 130 on the bottom surface of the first substrate 110.

The upper substrate 200 may include a second substrate 210, a light emitting structure 220, a reflective layer 213, an upper insulating layer 211, reflective electrodes 230, a second bonding insulating layer 240, and a second bonding electrode 250. The second substrate 210 may be a substrate for semiconductor single crystal growth. The second substrate 210 may include aluminum nitride (AlN), aluminum gallium nitride (AlGaN), zinc oxide (ZnO), gallium arsenide (GaAs), magnesium aluminate (MgAl₂O₄), magnesium oxide (MgO), lithium aluminate (LiAlO₂), lithium gallium oxide (LiGaO₂), gallium nitride (GaN), or a combination thereof. Forming the light emitting structure 220 may include sequentially forming a second semiconductor layer 222, an active layer 223, and a first semiconductor layer 221 on the bottom surface of the second substrate 210. Forming the second semiconductor layer 222 may include performing an epitaxial growth process on the bottom surface of the second substrate 210. The active layer 223 may be formed by an epitaxial growth process. The first semiconductor layer 221 may be formed by an epitaxial growth process. The epitaxial growth process may include, but not be limited to, a hydride vapor phase epitaxy (HVPE) process or a molecular beam epitaxy (MBE) process. Alternatively or additionally, at least one of the second semiconductor layer 222, the active layer 223, and the first semiconductor layer 221 may be formed by a metal organic chemical vapor deposition (MOCVD) process.

The upper substrate 200 may be bonded to the lower substrate 100 by a hybrid bonding process. For example, the upper substrate 200 may be disposed on the lower substrate 100 so that the second bonding electrodes 250 are vertically arranged with the first bonding electrodes 150. The upper substrate 200 or the lower substrate 100 may be pressed as indicated by arrows. Accordingly, the second bonding electrodes 250 may be bonded to the first bonding electrodes 150. The second bonding insulating layer 240 may be bonded to the first bonding insulating layer 140.

Referring to FIG. 6B, the second substrate 210 may be removed to expose the top surface of the second semiconductor layer 222. A thinning process may be further performed on the exposed top surface of the second semiconductor layer 222 to reduce the thickness of the second semiconductor layer 222.

Referring to FIG. 6C, a passivation layer 400 may be formed on the top surface of the second semiconductor layer 222 to cover the top surface of the second semiconductor layer 222. The passivation layer 400 may be provided on the top surface of the light emitting structure 220.

Referring to FIG. 6D, grooves 409 may be formed in the passivation layer 400. The grooves 409 may penetrate the passivation layer 400 to expose the top surface of the second semiconductor layer 222. For example, forming the grooves 409 may be performed by a patterning process including an exposure process and an etching process.

Referring to FIG. 6E, a preliminary grid electrode 300P may be formed in the grooves 409. The preliminary grid electrode 300P may fill the grooves 409 and extend onto the top surface 400a of the passivation layer 400. For example, the forming of the preliminary grid electrode 300P may be performed by a deposition process. The deposition process may include, but not be limited to, a physical vapor deposition process. As another example, the forming of the preliminary grid electrode 300P may be performed by an electroplating process. The top surface of the preliminary grid electrode 300P may be provided at a higher level than the top surface 400a of the passivation layer 400.

Referring to FIG. 6F, a planarization process may be performed on the preliminary grid electrode 300P to form the grid electrode 300. The planarization process may include removing a portion of the preliminary grid electrode 300P on the top surface 400a of the passivation layer 400. As a result of the planarization process, the top surface 400a of the passivation layer 400 may be exposed. The planarization process may include a chemical mechanical polishing (CMP) process. After the planarization process, the grid electrode 300 may be localized in the grooves 409. For example, the grid electrode 300 may not extend onto the top surface 400a of the passivation layer 400. Accordingly, a level difference between the top surface 300a of the grid electrode 300 and the top surface 220a of the light emitting structure 220 may be reduced by the planarization process. The top surface 300a of the grid electrode 300 may be provided at a level the same as or substantially similar to the top surface 400a of the passivation layer 400. For example, a thickness T1 of the grid electrode 300 may be 75% to 105% of a thickness T3 of the passivation layer 400. A level difference between the top surface 400a of the passivation layer 400 and the top surface 300a of the grid electrode 300 may be less than or equal to 250 nm.

Referring back to FIG. 3A, the lenses 500 may be formed on the top surface 400a of the passivation layer 400. The lenses 500 may further extend onto the top surface 300a of the grid electrode 300. Since the top surface 300a of the grid electrode 300 is provided at the same level or at a substantially similar level as the top surface 400a of the passivation layer 400, the lenses 500 may be easily formed. Accordingly, the manufacturing process of the light emitting device 10B may be simplified, and the manufacturing process efficiency of the light emitting device 10B may be improved. When the process of forming the preliminary grid electrode 300P described in the example of FIG. 5D is performed by an electroplating process, the grid electrode 300 may include the seed pattern 310 and the conductive electrode 320 as described in the example of FIG. 3C. Manufacturing of the light emitting device 10B may be completed by the examples described herein.

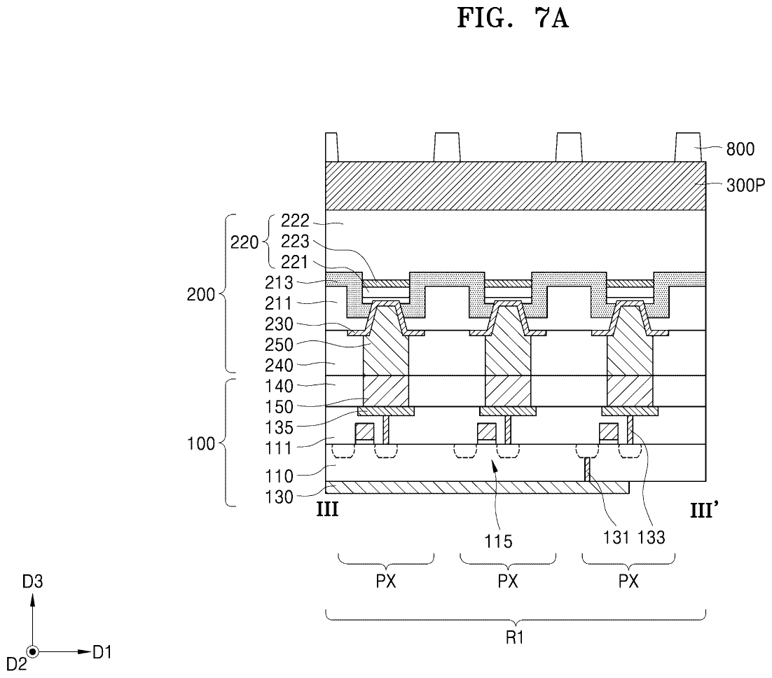

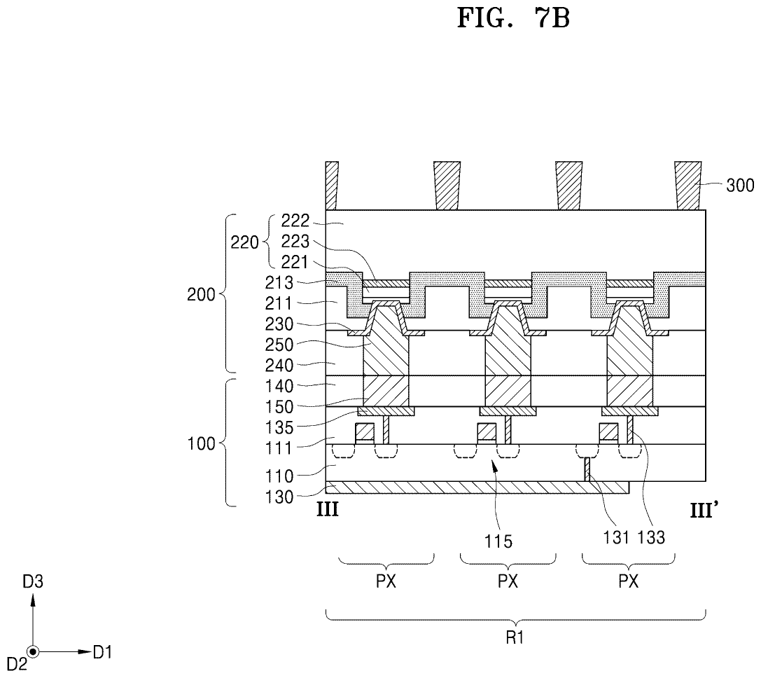

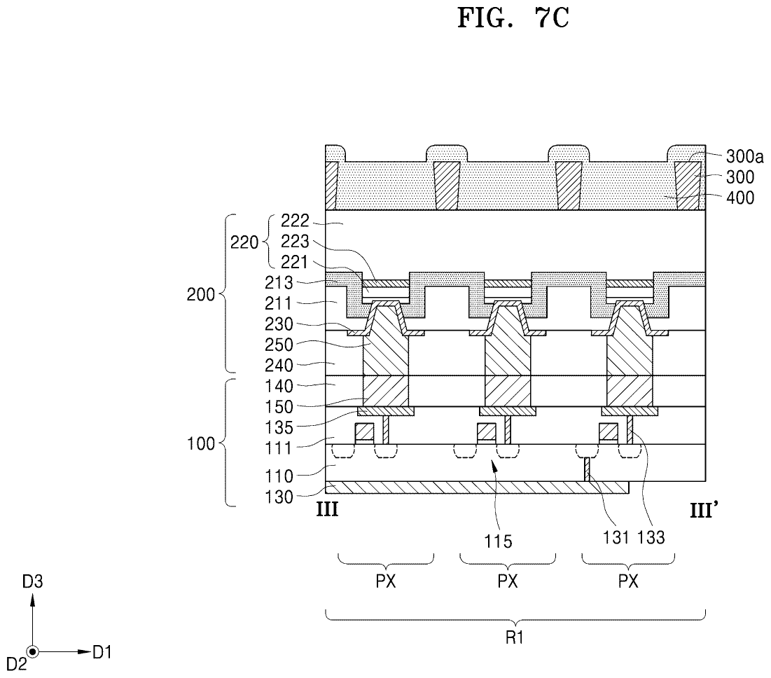

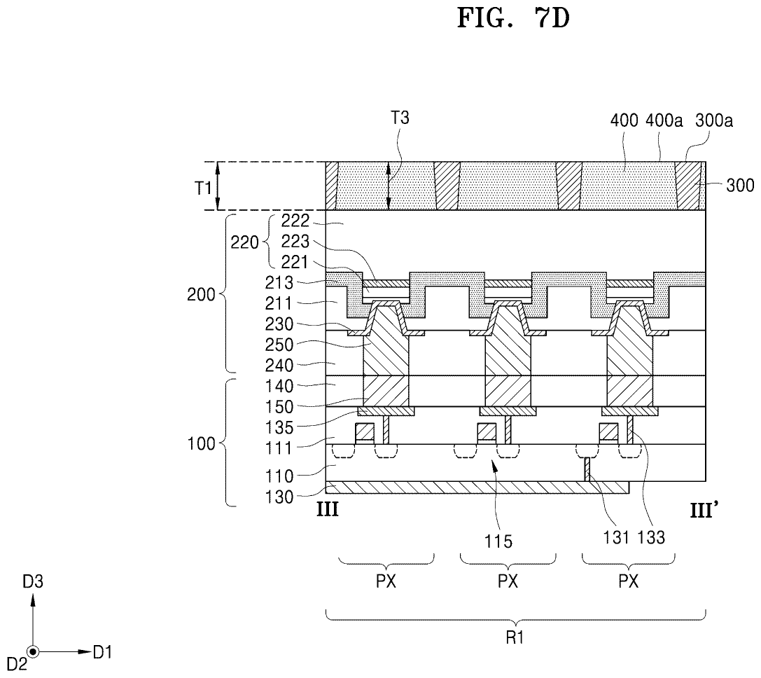

FIGS. 7A to 7D are views illustrating a method of manufacturing a light emitting device, according to embodiments, and correspond to cross-sections taken along a line III-III′ of FIG. 1B. Hereinafter, the description of FIGS. 7A to 7D is made together with reference to FIG. 1B. In addition, repeated descriptions of the light emitting device depicted in FIGS. 7A to 7D described above with reference to FIGS. 1A to 6F may be omitted for the sake of brevity.

Referring to FIG. 7A, a lower substrate 100 and an upper substrate 200 may be prepared. A bonding process between the lower substrate 100 and the upper substrate 200 may be performed. The preparation of the lower substrate 100, the preparation of the upper substrate 200, and the bonding process may be substantially the same as described with reference to FIG. 6A. For example, the upper substrate 200 may be bonded to the lower substrate 100 by a hybrid bonding process. Processes of removing the second substrate 210 and thinning the second semiconductor layer 222 as described with reference to FIG. 6B may be further performed.

The preliminary grid electrode 300P may be formed on the top surface of the light emitting structure 220. The preliminary grid electrode 300P may cover the top surface of the second semiconductor layer 222. For example, the forming of the preliminary grid electrode 300P may be performed by a deposition process. The deposition process may include, but is not limited to, a physical vapor deposition process. As another example, the forming of the preliminary grid electrode 300P may be performed by an electroplating process.

A photoresist pattern 800 may be formed on the preliminary grid electrode 300P. The photoresist pattern 800 may cover a top surface of a first portion of the preliminary grid electrode 300P and expose a top surface of a second portion of the preliminary grid electrode 300P. The photoresist pattern 800 may include an organic material.

Referring to FIG. 7B, a patterning process may be performed on the preliminary grid electrode 300P to form the grid electrode 300. The patterning process may include performing an etching process using the photoresist pattern 800 as a mask. The second portion of the preliminary grid electrode 300P may be removed by an etching process. The remaining first portion of the preliminary grid electrode 300P may form the grid electrode 300. As a result of the etching process, the top surface of the second semiconductor layer 222 may be exposed. Thereafter, the photoresist pattern 800 may be removed.

Referring to FIG. 7C, a passivation layer 400 may be formed on the grid electrode 300 and on the second semiconductor layer 222. The passivation layer 400 may cover a top surface 300a of the grid electrode 300, sidewalls of the grid electrode 300, and a top surface of the second semiconductor layer 222. The forming of the passivation layer 400 may be performed by a deposition process.

Referring to FIG. 7D, a planarization process may be performed on the passivation layer 400. The planarization process may include removing a portion of the passivation layer 400 on the top surface 300a of the grid electrode 300. As a result of the planarization process, the top surface 300a of the grid electrode 300 may be exposed. During the planarization process, a portion of the grid electrode 300 and an upper portion of the passivation layer 400 may be further removed.

The planarization process may include a chemical mechanical polishing (CMP) process. Accordingly, a level difference between the top surface 300a of the grid electrode 300 and the top surface 400a of the passivation layer 400 may be reduced by the planarization process. The top surface 300a of the grid electrode 300 may be provided at a level that is the same as or similar to the top surface 400a of the passivation layer 400. For example, after the planarization process is completed, the thickness T1 of the grid electrode 300 may be 75% to 105% of the thickness T3 of the passivation layer 400. A level difference between the top surface 400a of the passivation layer 400 and the top surface 300a of the grid electrode 300 may be less than or equal to 250 nm.

Referring back to FIG. 3A, the lenses 500 may be formed on the top surface 400a of the passivation layer 400. The lenses 500 may further extend onto the top surface 300a of the grid electrode 300. Since the top surface 300a of the grid electrode 300 is provided at substantially the same or similar level as the top surface 400a of the passivation layer 400, the lenses 500 may be easily formed. When the process of forming the preliminary grid electrode 300P described in the example of FIG. 7A is performed by an electroplating process, the grid electrode 300 may include the seed pattern 310 and the conductive electrode 320 as described in the example of FIG. 3D. Manufacturing of the light emitting device 10B may be completed by the examples described so far.

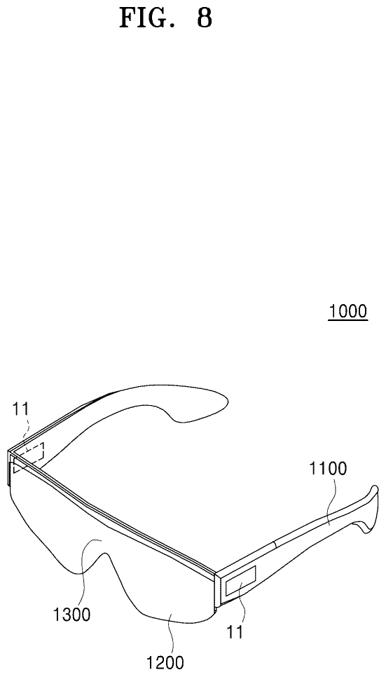

FIG. 8 is a schematic diagram of an electronic device including a light emitting device, according to embodiments.

Referring to FIG. 8, an electronic device 1000 may be and/or may include a glasses-type display that may be a wearable device. The electronic device 1000 may be and/or may include a head mounted, glasses-type, or goggle-type virtual reality (VR) device, an augmented reality (AR) device, or a mixed reality (MR) device that may provide a virtual reality and/or provide a virtual image combined with an external real landscape.

The electronic device 1000 may include a pair of temples 1100, a pair of optical coupling lenses 1200, a bridge 1300, and display apparatuses 11. The temples 1100 may extend in one direction. The temples 1100 may be spaced apart from each other and extend parallel to each other. The temples 1100 may be folded toward the bridge 1300. The bridge 1300 may be provided between the optical coupling lenses 1200 to connect the optical coupling lenses 1200 to each other. The optical coupling lenses 1200 may include a light guide plate.

The display apparatus 11 may be disposed on each of the temples 1100 and may generate an image on the optical coupling lenses 1200. The display apparatuses 11 may include the light emitting device 10 described in the examples of FIGS. 1A to 1E, the light emitting device 10AA of FIGS. 1F and 1G, the light emitting device 10A of FIG. 2A, the light emitting device 10B of FIG. 3A, the light emitting device 10C of FIG. 3B, the light emitting device 10D of FIG. 4A and 4B, and/or the light emitting device 10E of FIG. 5.

While the present disclosure has been particularly shown and described with reference to embodiments thereof, it is to be understood that various changes in form and details may be made therein without departing from the spirit and scope of the following claims.

What is claimed is:

1. A light emitting device, comprising:
a substrate comprising a pixel array region and an edge region, the pixel array region comprising a plurality of pixel regions;
a light emitting structure on the pixel array region of the substrate;
a grid electrode on the light emitting structure;
a plurality of lenses on the light emitting structure; and
a common electrode on the edge region of the substrate,
wherein the grid electrode is provided between two adjacent pixel regions from among the plurality of pixel regions of the substrate,
wherein the light emitting structure comprises a semiconductor stack comprising a first semiconductor layer, an active layer, and a second semiconductor layer, and
wherein the second semiconductor layer is electrically coupled with the common electrode through the grid electrode.

2. The light emitting device of claim 1, further comprising:
a conductive pattern on at least a portion of a top surface of the grid electrode and on a top surface of the common electrode,
wherein the grid electrode is electrically coupled with the common electrode through the conductive pattern.

3. The light emitting device of claim 1, wherein the grid electrode is electrically coupled with the common electrode through a conductive pattern.

4. The light emitting device of claim 1, wherein at least one of the plurality of lenses extends onto a top surface of the grid electrode.

5. The light emitting device of claim 1, further comprising:
a passivation layer between the light emitting structure and the plurality of lenses,
wherein the grid electrode is provided in the passivation layer.

6. The light emitting device of claim 1, wherein the light emitting structure comprises a plurality of light emitting units,
wherein the plurality of light emitting units are respectively provided on the plurality of pixel regions of the substrate,
wherein the grid electrode is interposed between the plurality of light emitting units,
wherein the grid electrode comprises at least one of a metal material, a transparent conductive oxide, or a combination thereof,
wherein the metal material comprises at least one of aluminum (Al), copper (Cu), gold (Au), platinum (Pt), palladium (Pd), silver (Ag), or alloys thereof, and
wherein the transparent conductive oxide comprises at least one of indium tin oxide (ITO), zinc-doped indium tin oxide (ITO:Zn), indium zinc oxide (IZO), gallium indium oxide (GIO), tin zinc oxide (SnZnO₃), fluorine-doped tin oxide (SnO₂:F), aluminum-doped zinc oxide (ZnO:Al), gallium-doped zinc oxide (Ga₂ZnO₄), or a combination thereof.

7. The light emitting device of claim 1, wherein the grid electrode is not provided between adjacent pixel regions from among the plurality of pixel regions.

8. The light emitting device of claim 1, wherein the grid electrode comprises:
a bottom surface; and
a sidewall inclined with respect to the bottom surface.

9. A light emitting device, comprising:
a substrate comprising a pixel array region and an edge region, the pixel array region comprising a plurality of pixel regions;
a light emitting structure on each of the plurality of pixel regions;
a passivation layer on the light emitting structure;
a grid electrode in the passivation layer and on the light emitting structure and between two adjacent pixel regions from among the plurality of pixel regions; and
a plurality of lenses on a top surface of the passivation layer,
wherein the light emitting structure comprises a semiconductor stack comprising a first semiconductor layer, an active layer, and a second semiconductor layer, and
wherein the second semiconductor layer is electrically coupled with a common electrode through the grid electrode.

10. The light emitting device of claim 9, further comprising:
a conductive pattern on at least a portion of a top surface of the grid electrode and on a top surface of the common electrode,
wherein the common electrode is disposed on the edge region of the substrate;
wherein the grid electrode is electrically coupled with the common electrode through the conductive pattern, and
wherein the edge region of the substrate at least partially surrounds the pixel array region in a plan view.

11. The light emitting device of claim 9, wherein the plurality of lenses at least partially cover at least a portion of a top surface of the grid electrode.

12. The light emitting device of claim 11, wherein a level difference between a first level of the top surface of the passivation layer and a second level of the top surface of the grid electrode is less than or equal to 250 nanometers (nm).

13. The light emitting device of claim 9, wherein a first refractive index of the passivation layer is lower than a second refractive index of the light emitting structure, and wherein the first refractive index is greater than refractive indices of the plurality of lenses.

14. The light emitting device of claim 9, wherein the passivation layer comprises:
a first passivation layer on the light emitting structure; and
a second passivation layer on the first passivation layer, and
wherein the grid electrode at least partially penetrates the first passivation layer and the second passivation layer.

15. The light emitting device of claim 14, wherein a first refractive index of the first passivation layer is less than a second refractive index of the light emitting structure,
wherein a third refractive index of the second passivation layer is less than the first refractive index of the first passivation layer, and
wherein each of the plurality of lenses comprises a lower refractive index than the third refractive index of the second passivation layer.

16. The light emitting device of claim 9, wherein a top width of a top surface of the grid electrode is greater than a bottom width of a bottom surface of the grid electrode.

17. A display apparatus, comprising:
a lower substrate comprising a semiconductor substrate, a plurality of wiring lines on a bottom surface of the semiconductor substrate, a plurality of transistors on a top surface of the semiconductor substrate, a first bonding insulating layer on the top surface of the semiconductor substrate, and first bonding electrodes within the first bonding insulating layer;
an upper substrate comprising a second bonding insulating layer on the first bonding insulating layer, a plurality of second bonding electrodes on the first bonding electrodes, and a light emitting structure on at least one of the plurality of second bonding electrodes, the upper substrate comprising a pixel array region and an edge region, and the pixel array region comprising a plurality of pixel regions;
a grid electrode on the light emitting structure;
a plurality of lenses on the light emitting structure;
a common electrode provided on the edge region of the upper substrate and electrically coupled with another second bonding electrode from among the plurality of second bonding electrodes; and
a conductive pattern on the grid electrode and on the common electrode,
wherein the grid electrode is electrically coupled with the common electrode through the conductive pattern,
wherein the grid electrode is between two adjacent pixel regions from among the plurality of pixel regions of the upper substrate,
wherein the light emitting structure comprises a semiconductor stack comprising a first semiconductor layer, a second semiconductor layer on the first semiconductor layer, and an active layer between the first semiconductor layer and the second semiconductor layer, and
wherein the grid electrode is electrically coupled with the second semiconductor layer.

18. The display apparatus of claim 17, wherein an angle between the bottom surface and a sidewall of the grid electrode is obtuse, and
wherein at least one of the plurality of lenses extends further onto a top surface of the grid electrode to at least partially cover the top surface of the grid electrode.

19. The display apparatus of claim 17, further comprising:
a passivation layer between the light emitting structure and the plurality of lenses,
wherein the grid electrode is provided in the passivation layer and on the top surface of the second semiconductor layer, and
wherein a first refractive index of the passivation layer is lower than a second refractive index of the light emitting structure, and
wherein the first refractive index of the passivation layer is greater than refractive indices of the plurality of lenses.

20. The display apparatus of claim 17, wherein the light emitting structure comprises a plurality of light emitting units,
wherein the plurality of light emitting units are respectively provided on the plurality of pixel regions of the upper substrate, and
wherein the grid electrode is between the plurality of light emitting units and is in contact with a sidewall of the second semiconductor layer.
